(19) United States
(12) Patent Application Publication
(10) Pub. No.: US 2009/0296798 A1
(43) Pub. Date: Dec. 3, 2009

(54) HSDPA CO-PROCESSOR FOR MOBILE TERMINALS

(75) Inventors: Rami Banna, New South Wales (AU); Mark A. Bickerstaff, New South Wales (AU); Matthew E. Cooke, New South Wales (AU); Adriel P. kind, New South Wales (AU); Yi-Chen Li, New South Wales (AU); Oliver Ridler, New South Wales (AU); Uwe Sontowski, New South Wales (AU); Charles N. A. Thomas, New South Wales (AU); Long Ung, New South Wales (AU); Koen Van den Beld, New South Wales (AU); Benjamin J. Widdup, New South Wales (AU); Graeme K. Woodward, New South Wales (AU); Dominic Wing-Kin Yip, New South Wales (AU); Gongyu Zhou, New South Wales (AU)

Correspondence Address: MENDELSOHN, DRUCKER, & ASSOCIATES, P.C., 1500 JOHN F. KENNEDY BLVD., SUITE 405, PHILADELPHIA, PA, 19102, US

(73) Assignee: Agere Systems Inc,., Allentown, PA (US)

(21) Appl. No.: 12/295,683

(22) PCT Filed: Apr. 5, 2007
(86) PCT No.: PCT/US07/66028

§ 371 Date: Feb. 17, 2009

Related U.S. Application Data
(60) Provisional application No. 60/789,347, filed on Apr. 5, 2006.

(51) Int. Cl. H03H 7/40; H04W 4/00

(52) U.S. Cl. 375/229; 370/328

(57) ABSTRACT

In one embodiment, an HSDPA co-processor for 3GPP Release 6 Category 8 (7.2 Mb/s) HSDPA that provides all chip-rate, symbol-rate, physical-channel, and transport-channel processing for HSDPA in 90 nm CMOS. The co-processor design is scalable to all HSDPA data rates up to 14 Mb/s. The coprocessor implements an Advanced Receiver based on an NLMS equalizer, supports RX diversity and TX diversity, and provides up to 6.4 dB better performance than a typical single-antenna rake receiver. Thus, 3GPP R6 HSDPA functionality can be added to a legacy R99 modem using an HSDPA co-processor consistent with embodiments of the present invention, at a reasonable incremental cost and power.

### CROSS-REFERENCE TO RELATED APPLICATIONS

This application claims the benefit of the filing date of U.S. provisional application no. 60/789,347, filed on May 5, 2006, the teachings of which are incorporated herein by reference.

### BACKGROUND OF THE INVENTION

1. Field of the Invention

The present invention relates generally to a mobile communications system, and in particular, to transmitting and receiving information in a mobile communications system supporting a high-speed downlink-packet access (HSDPA) scheme.

2. Description of the Related Art

Universal Mobile Telecommunications Service (UMTS) is a third-generation (3G) broadband, packet-based mobile network that allows the transmission of text, digitized voice, video, and multimedia at data rates up to 2 Mb/s. The goal of UMTS, which is based on the Global System for Mobile (GSM) communication standard, is to offer a consistent set of services to mobile computer and phone users, no matter where they are located in the world.

UMTS mobile wireless networks conforming to Third-Generation Partnership Project (3GPP) Release 99 (R99) standards have now been widely deployed, with more than 90 operational networks in over 35 countries. However, the goal of ubiquitous mobile broadband data has not yet been realized, due to the absence of an efficient high-speed packet-switched transport mechanism in the downlink. High-Speed Downlink Packet Access (HSDPA), a standard defined as part of the 3GPP Release 5 (R5) and Release 6 (R6) standards, provides high-speed downlink data channels that can be shared efficiently between multiple users. HSDPA offers increased data rates (up to 14 Mb/s) as well as improved error-control handling and other techniques which increase overall network performance and increase the spectral efficiency of the radio interface.

HSDPA is characterized by three new physical channel types: the high-speed shared control channel (HS-SCCH), the high-speed physical downlink shared channel (HS-PDSCH), and the high-speed dedicated physical control channel (HS-DPCCH). HS-SCCH is a downlink control channel that informs a mobile terminal when HSDPA downlink data is scheduled for that terminal and instructs the terminal on how to receive and decode it. A mobile terminal can simultaneously monitor up to four HS-SCCH channels. HS-PDSCH is a downlink channel that carries HSDPA user data. Multiple HS-PDSCHs (up to 10 for HSDPA Category 8 and 15 for Category 10) can be assigned to each mobile terminal for each 2 ms HSDPA transmission time interval (TTI). HS-DPCCH is an uplink control channel, which is used by a mobile terminal to report the downlink channel quality and to request re-transmissions when HSDPA data is not received correctly.

HSDPA uses both the QPSK (Quadrature Phase-Shifting Keying) and 16-QAM (Quadrature Amplitude Modulation) modulation schemes, pursuant to the Wide-Band CDMA (WCDMA) standard. The QPSK modulation scheme transmits two data bits per symbol, and the 16-QAM modulation scheme transmits four bits per symbol. While R99 supports only QPSK modulation, HSDPA uses 16QAM modulation on the HS-PDSCH channel to double the potential data rate in favorable channel conditions.

An HSDPA mobile terminal at a first node measures the downlink channel quality and transmits this information in the form of a channel quality indicator (CQI) to a second node on the HS-DPCCH channel. The second node uses the CQI to dynamically vary the number of HS-PDSCH channels, the modulation scheme, and the code rate, so as to make best use of the varying channels. The second node may also use the CQI as part of an opportunistic scheduling algorithm, which favors mobile terminals with the best CQI, thus maximizing the overall HSDPA throughput.

HSDPA also introduces a physical-layer hybrid automatic repeat request (HARQ) function to improve efficiency and reduce latency in the event of errors. If an HSDPA transport block is received with errors, then the mobile terminal requests a retransmission by sending a negative acknowledgement (NACK) message on the HS-DPCCH channel, and if there are no errors, then an acknowledgement (ACK) message is sent. Retransmitted data is combined with the original transmission at the mobile terminal to increase the likelihood of successful decoding.

Unlike the case of R99 channels, in which power control is used to achieve a constant data rate, mobile terminals with high-performance HSDPA receivers will, on average, achieve relatively higher HSDPA data rates, resulting in a situation that benefits both the network operator and the mobile user. It is therefore important to maximize HSDPA receiver performance. However, adding HSDPA to the existing R99 design of a mobile terminal has previously been problematic, because the added complexity and increased performance requirements of HSDPA have previously made modifying the existing R99 design very difficult and inefficient.

### SUMMARY OF THE INVENTION

Problems in the prior art are addressed in accordance with the principles of the present invention by adding a co-processor implementing the new HSDPA functionality to an existing R99 mobile terminal design. In certain embodiments, this co-processor adds baseband layer-1 (L1) R5 and R6 HSDPA functionality to an existing R99-only design, and high receiver performance is achieved through the use of an advanced receiver based on normalized least-mean square (NLMS) equalizers and two-antenna receive (RX) diversity. While the co-processor in certain embodiments described herein supports HSDPA Category 8, which has a maximum data rate of 7.2 Mb/s, the design can be scaled to support all HSDPA categories (including at least HSDPA Category 10 at a maximum data rate of 14 Mb/s), in alternative embodiments.

In one embodiment, the present invention provides a method for processing received signals. The method includes: (a) receiving first and second signals; (b) equalizing the first received signal using one or more pilot reference signals to provide a first equalized signal; (c) decoding one or more data channels of the first equalized signal to recover an original data sequence for the one or more data channels; and (d) equalizing the second received signal using, as a reference signal, the recovered original data sequence, in combination with one or more pilot reference signals. The equalizing in steps (b) and (d) includes: (i) using a filter to filter the received signal based on a set of filter tap coefficients adaptively generated by calculating an error signal, and (ii) updating the filter tap coefficients based on the error signal. The filter has a sampling window defining a time span during which signal samples are gathered. The sampling window is adaptable, based on a changing position of one or more rays, each ray being a version of one of the first and second signals that travels along a given path.

In another embodiment, the present invention provides an apparatus for processing received signals. The apparatus is adapted to: (a) receive first and second signals; (b) equalize the first received signal using one or more pilot reference signals to provide a first equalized signal; (c) decode one or more data channels of the first equalized signal to recover an original data sequence for the one or more data channels; and (d) equalize the second received signal using, as a reference signal, the recovered original data sequence, in combination with one or more pilot reference signals. The equalizing in steps (b) and (d) includes: (i) using a filter to filter the received signal based on a set of filter tap coefficients adaptively generated by calculating an error signal, and (ii) updating the filter tap coefficients based on the error signal. The filter has a sampling window defining a time span during which signal samples are gathered. The sampling window is adaptable, based on a changing position of one or more rays, each ray being a version of one of the first and second signals that travels along a given path.

### BRIEF DESCRIPTION OF THE DRAWINGS

Other aspects, features, and advantages of the present invention will become more fully apparent from the following detailed description, the appended claims, and the accompanying drawings in which like reference numerals identify similar or identical elements.

FIG. 1 illustrates an exemplary HSDPA co-processor consistent with one embodiment of the present invention;

FIG. 2 illustrates the internal structure of the advanced receiver (AR) of the HDSPA co-processor of FIG. 1;

FIG. 3 illustrates the internal structure of the physical and transport channel processor (PTCP) of the HSDPA co-processor of FIG. 1;

FIG. 4 is a table showing estimated size and peak power based on synthesis results for Category 8 during testing of the HSDPA co-processor of FIG. 1;

FIG. 5 is a table showing 3GPP R6 Category 8 throughput-performance simulations for the HSDPA co-processor of FIG. 1 in a PA3 channel using QPSK modulation;

FIG. 6 is a table showing 3GPP R6 Category 8 throughput-performance simulations for the HSDPA co-processor of FIG. 1 in a VA30 channel using 16 QAM modulation;

FIG. 7 is a block diagram depicting an exemplary embodiment of a communications circuit in accordance with an aspect of the present invention;

FIG. 8 is a block diagram showing another exemplary embodiment of a communications circuit in accordance with another aspect of the present invention;

FIG. 9 depicts parameters pertaining to certain techniques of the present invention;

FIG. 10 depicts three possible exemplary scenarios wherein tap repositioning may be required when employing aspects of the present invention;

FIG. 11 depicts Priority 1 and Priority 2 re-positioning in accordance with an exemplary embodiment of the present invention;

FIG. 12 is a flow chart depicting exemplary method steps for receiving a plurality of time-varying significant rays in a communications circuit, according to yet another aspect of the present invention;

FIG. 13 illustrates use of masking patterns to change size and/or location of a sampling window in accordance with an exemplary embodiment of the present invention;

FIG. 14 depicts receiver bit error rate (BER) and tap span allocation when an exemplary embodiment of the present invention is applied under the 3GPP birth and death propagation channel;

FIG. 15 depicts a first criteria to be met by a tap span in an exemplary embodiment of the present invention;

FIG. 16 depicts another criteria to be met by a tap span in an exemplary embodiment of the present invention;

FIG. 17 illustrates parameters pertaining to certain tap span calculation techniques in accordance with aspects of the present invention;

FIG. 18 shows BER using a fixed equalizer tap span in a 3 km/h Rayleigh fading propagation channel;

FIG. 19 depicts a plot similar to FIG. 12 but in the case where a variable equalizer tap span is employed using certain techniques of the present invention;

FIG. 20 compares the BER from the cases depicted in FIGS. 12 and 13;

FIG. 21 provides further details about varying tap span using a mask pattern in accordance with principles of the present invention;

FIG. 22 depicts an architectural diagram for a simple chip rate Normalized Least-Mean Square (NLMS) equalizer receiver;

FIG. 23 depicts a diagram similar to FIG. 16 but for a receiver with tap mask capabilities;

FIG. 24 depicts an exemplary implementation of a masking block using exemplary techniques of the present invention;

FIG. 25 shows a bit error rate performance curve for an NLMS equalizer with and without tap masking capabilities;

FIG. 26 shows a simplified block diagram of one implementation of a prior-art receiver that uses a pilot channel to equalize received signals;

FIG. 27 shows a simplified block diagram of a receiver according to one embodiment of the present invention that generates additional reference signals from received data signals and uses the reference signals to equalize the received signals;

FIG. 28 shows a simplified block diagram of a receiver according to one embodiment of the present invention that generates additional reference signals from received data signals, selects a step size from a look-up table based on the additional reference signals, and uses both the reference signals and the step size to equalize the received signals;

FIG. 29 shows pseudocode used by the receiver of FIG. 28 to select step sizes according to one embodiment of the present invention;

FIG. 30 shows a table which lists the parameters used by the pseudocode of FIG. 29;

FIG. 31 shows a simplified block diagram of one embodiment of the reference calculator of the receiver of FIG. 28;

FIG. 32 shows a simplified block diagram of an apparatus according to one embodiment of the present invention that has two receivers which can be used to receive transmit-diverse signals or to generate additional reference signals; and

FIG. 33 shows a simplified block diagram of a receiver according to one embodiment of the present invention that has more than one reference generator.

### DETAILED DESCRIPTION

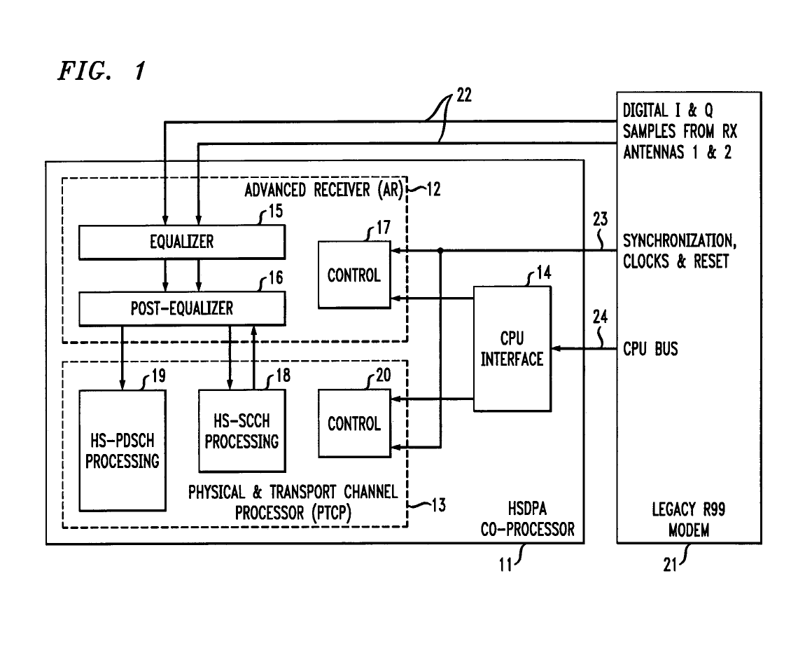

FIG. 1 illustrates an exemplary HSDPA co-processor 11 consistent with one embodiment of the present invention. Co-processor 11 has two main functional hardware blocks, Advanced Receiver (AR) 12 and Physical and Transport Channel Processor (PTCP) 13, and further includes a CPU interface 14.

Co-processor 11 carries out all of the layer-1 (L1) digital baseband processing for the HS-SCCH control channel and the HS-PDSCH data channels and is designed to co-exist with a legacy R99 modem 21, which implements all of the HSDPA non-L1 functionality described in the HSPDA standards. Legacy modem 21 provides all of the front-end support, including filtering, automatic frequency control, automatic gain control, multipath searching, higher-layer interfacing, synchronization, and related functionality. Legacy modem 21 also provides uplink (UL) support for transmission of the HS-DPCCH channel, which contains CQI and ACK/NACK values determined by co-processor 11.

Co-processor 11 has a hardware data path 22 for processing the HSDPA downlink channels and a software data path 23 for interfacing with embedded software for control and scheduling of the hardware. The hardware of co-processor 11 does not include its own CPU core, but instead provides a CPU-interface bus 24, which allows the embedded software to reside on an existing system CPU (not shown), e.g., within legacy modem 21. Thus, embedded software size and complexity are relatively low, as compared to other mobile handset software requirements.

Legacy modem 21 provides to co-processor 11, via data path 22, digitized baseband samples, e.g., in-phase (I) and quadrature (Q) samples, based on signals originating at antennas 1 and 2 (not shown) of legacy modem 21. Legacy modem 21 also provides to co-processor 11 synchronization, clock, and reset signals via data path 23, and CPU instructions via data path 24.

AR 12 includes chip-level equalizer 15, post-equalizer 16, and control block 17. Equalizer 15 implements multiple normalized least-mean square (NLMS) chip-level equalizers having a total of up to 32 taps (i.e., a 16-chip span, with two filter taps per chip). Each tap adjusts, at a specific time, the signal being processed, to shape it during transmission, thereby outputting a signal to post-equalizer 16 that should closely approximate the original pre-transmission signal. Equalizer 15 performs operations at the chip level, on individual chips, which are data symbols multiplied by channelization codes. Equalizer 15 is optimized to receive the low-delay spread channels defined in the 3GPP standards for HSDPA and supports Space-Time Transmit Diversity (STTD), Closed-Loop Transmit Diversity (CLTD) mode 1, and two-antenna RX diversity. Post-equalizer 16 performs further processing of signals provided by equalizer 15, including descrambling, despreading, and demapping, as will be described in further detail below. Control block 17 receives CPU instructions via CPU interface 14 and synchronization, clock, and reset signals from legacy R99 modem 21, which instructions control the operation of the various components of equalizer 15 and post-equalizer 16.

PTCP 13 includes HS-SCCH processing block 18, HS-PDSCH processing block 19, and control block 20. HS-SCCH processing block 18 decodes the HS-SCCH downlink HSDPA control channels, which must be done before the corresponding HS-PDSCH channel can be received. HS-PDSCH processing block 19 decodes the high-speed HSDPA data channels based on information obtained from the corresponding decoded HS-SCCH. Control block 20 receives CPU instructions via CPU interface 14 and synchronization, clock, and reset signals from legacy R99 modem 21 which instructions control the operation of the various components of HS-SCCH processing block 18 and HS-PDSCH processing block 19.

CPU interface 14 provides instructions from the CPU to control block 17 of AR 12 and to control block 20 of PTCP 13.

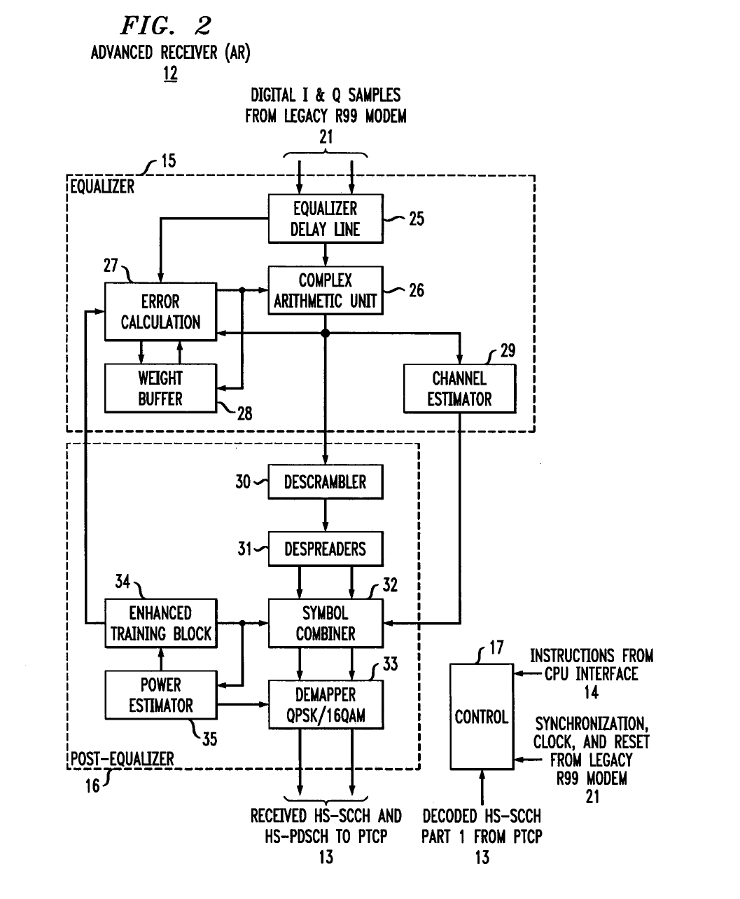

FIG. 2 illustrates the internal structure of AR 12, including equalizer 15, post-equalizer 16, and control block 17.

Equalizer 15 includes equalizer delay line 25, complex arithmetic unit 26, error-calculation block 27, weight buffer 28, and channel estimator 29.

Traditional rake receivers depend on spreading sequences with good auto-correlation properties, which allow the detection and processing of individual multipaths in frequency-selective multipath channels. In practice, ideal codes cannot be designed, so this technique is suboptimal and results in inter-code interference (ICI) and inter-symbol interference (ISI), which a rake receiver cannot adequately suppress. With the higher data rates and capacity demands of HSDPA, simple rake-based detection is no longer adequate. ICI arises from the effect of the multipath channel (e.g., fading) destroying the orthogonality between channelization (or “spreading”) codes. ISI is also caused by the time-dispersive nature of the multipath channel and the imperfect auto-correlation properties of each channelization code. Both effects are exacerbated by the facts that the channelization codes are relatively short (length 16), and that HSDPA uses 16QAM modulation.

In equalizer 15, as in the method of equalization used in many communications receivers (which can also be applied to UMTS), the fundamental unit to be equalized is the chip. Chip equalization attempts to mitigate the unwanted effects of the multipath channel by filtering received samples to restore the orthogonality of the multicode components, to form a better estimate of each transmitted chip.

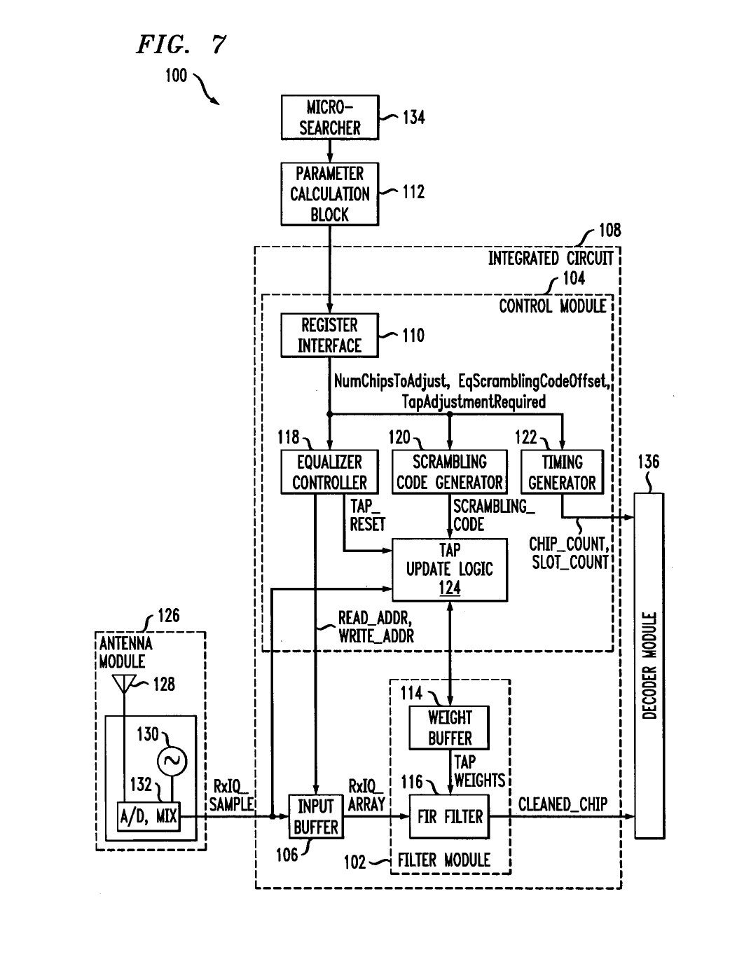

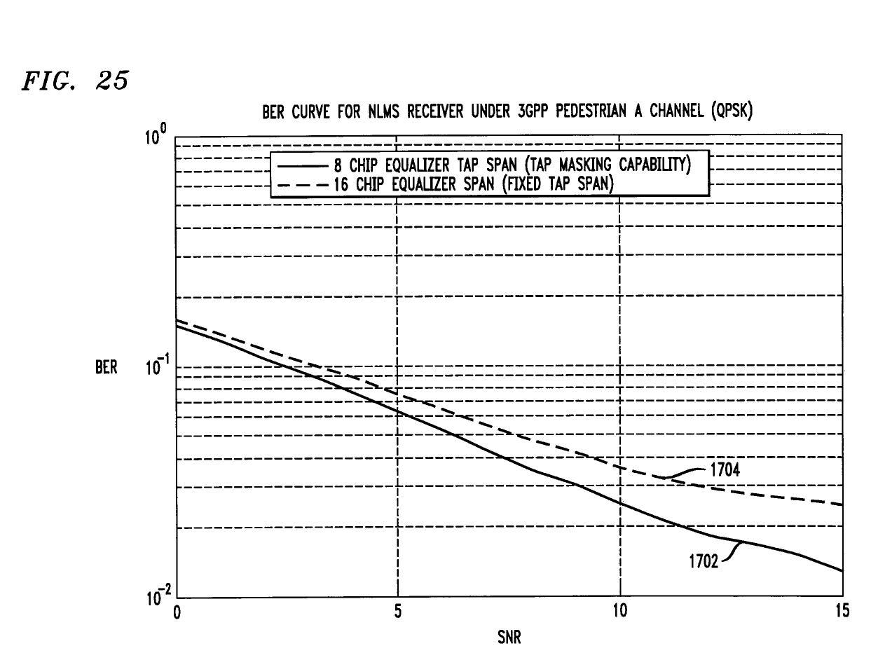

Equalizer delay line 25 stores in a FIFO arrangement the received I & Q samples (e.g., 2 samples per chip), based on signals originating at antennas 1 and 2 (not shown). These I & Q samples are made available to both complex arithmetic unit 26 and error-calculation block 27. Complex arithmetic unit 26 implements a FIR filter based on a series of complex multiplication and complex addition units and outputs a filtered (equalized) chip estimate. Error-calculation block BC calculates the error between the filtered chip estimate and the expected chip and uses this error signal to calculate new filter tap weights for every chip. Through this process the filter tap weights adapt to follow and compensate for (i.e., equalize) the changing channel response. Multiple logical equalizers of potentially-different sizes may be implemented in a time-multiplexed fashion. The implementation of multiple logical equalizers of varying sizes is fully described below with reference to FIGS. 7-25, below. In particular, the FIR filters of equalizer 15 have sampling windows defining time spans during which signal samples are gathered. The duration and/or location of the sampling windows are modifiable based on the changing position of one or more rays carrying the received samples that travels along different paths.

Two fundamentally different methods can possibly be used to compute and update tap coefficients, either block or adaptive. Block methods assume that the channel is sufficiently static over a block of chips and compute a single-filter response to be used over each block. The required frequency of coefficient updates is a function of the Doppler frequency of the channel. The disadvantages of block methods are poor tracking of fast-fading channels and the need for a costly hardware block to measure the channel-impulse response.

Equalizer 15 employs an adaptive method, which updates the filter coefficients continuously (e.g., at each chip period) by adding a correction term to the existing filter coefficients and provides automatic real-time tracking of channel conditions. Such an adaptive method is implemented in error-calculation block 27 by an NLMS adaptive-equalizer algorithm, as described, e.g., in Hooli, “Equalization in WCDMA terminals,” thesis in University of Oulu, Finland (2003), incorporated herein by reference in its entirety. NLMS approximates an optimal minimum-mean squared error (MMSE) solution, but with reduced complexity and without the need for a channel-impulse response (CIR). Equalizer 15 may also implement a tap-coefficient averaging scheme, as fully described in U.S. patent application Ser. No. 11/710,212, filed Feb. 23, 2007 as attorney docket no. Cooke 2-7-4, incorporated herein by reference in its entirety.

A continuous pilot sequence, CPICH, transmitted by the transmitting node with which legacy modem 21 is in communication, is used for training, as discussed, e.g., in Frank et al., “Adaptive interference suppression for the downlink of a DSCDMA system with long spreading sequences,” J. VLSI Sig. Proc., vol. 30, no. 1, January 2002, at pp. 273-291, incorporated herein by reference in its entirety. Error-calculation block 27 compares the expected scrambled (and spread) pilot sequence with the output of equalizer delay line 25 for a given chip, to provide an error value for that chip representing the accuracy of the equalizer in approximating the original pre-transmission signal. An NLMS update loop comprising complex arithmetic unit 26, error-calculation block 27, and weight buffer 28 uses this error value to compute an estimated gradient vector to direct the tap coefficients towards their optimal values.

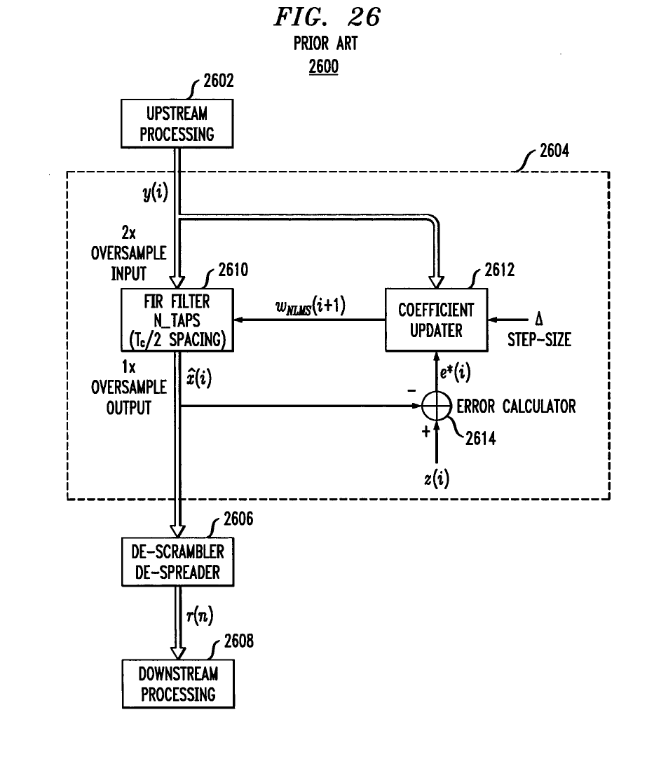

The optimal equalizer step size changes as a function of mobile terminal velocity, and enhanced-training block 34 of post-equalizer 16 therefore desirably estimates step size based on a Doppler velocity estimate, as fully described in U.S. patent application Ser. No. 11/289,943, filed Nov. 30, 2005 as attorney docket no. Kind 1, incorporated herein by reference in its entirety. Enhanced training block 34 also desirably uses non-pilot reference channels to improve equalizer training and receiver performance, as fully described below with reference to FIGS. 26-33.

Enhanced training block 34 of post-equalizer 16 provides the estimated step size to error-calculation block 27, which error-calculation block 27 uses in updating tap coefficients, by applying an NLMS algorithm to the step size and calculated error values.

Weight buffer 28 is coupled to error-calculation block 27 and is configured to store tap-coefficient values generated by error-calculation block 27.

Equalizer 15 is configured to act as two logical NLMS equalizers EQ1 and EQ2 (not separately shown) implemented in a single physical hardware block (i.e., equalizer 15), which is time-multiplexed between the two logical equalizers, e.g., as fully disclosed in U.S. Provisional Application Ser. No. 60/826,280, filed on Sep. 20, 2006. Thus, equalizer 15 outputs two streams of “cleaned” chip estimates to post-equalizer 16. Equalizer 15 is “reconfigurable” in that its two logical equalizers (EQ1, EQ2) can be configured in any of four different operating modes: (a) low power mode, wherein EQ1 is active on antenna 1 and EQ2 is not used, (b) enhanced training mode, wherein EQ1 and EQ2 are both active on antenna 1, (c) RX-diversity mode, wherein EQ1 receives on antenna 1, while EQ2 receives on antenna 2, and (d) TX-diversity mode, wherein EQ1 transmits on antenna 1, while EQ2 transmits on antenna 2. For example, if one antenna is experiencing a poor signal, one or more other antennas might be experiencing a better signal. These signals may then be combined into one signal, and when combined appropriately, the resulting signal quality is better than that of each individual signal. Equalizer 15 desirably implements a fast-startup method, as fully disclosed in U.S. Provisional Application Ser. No. 60/826,391, filed Sep. 2, 2006.

Channel estimator 29 of equalizer 15 correlates the output of complex arithmetic unit 26 with a pilot channel, which is a downlink channel carrying a pre-defined bit sequence. Such pilot channel is typically broadcast over the entire cell, so that such that user equipment such as mobile phones can determine the channel condition between the equipment and the transmitting antenna. In a case when transmit diversity such as space-time coded transmit diversity (STTD) is employed, different bit sequences can be transmitted on the two transmitting antennas.

Post-equalizer 16 implements descrambling, HS-SCCH and HS-PDSCH despreading, parameter estimation, TX/RX-diversity scaling and combining, Log-Likelihood Ratio (LLR) calculation, and QPSK/16QAM demapping. To achieve this functionality, post-equalizer 16 includes descrambler 30, despreaders 31, symbol combiner 32, demapper 33, enhanced training block 34, and power estimator 35. Descrambler 30 multiplies the conjugate of the scrambling code employed in the given scheme with the output from complex arithmetic unit 26 of equalizer 15. Descrambler 30 desirably uses a method to determine selection of a scrambled data channel before receipt of an entire data block, as fully disclosed in U.S. Patent Application Pub. No. 2006/0239457 A1, incorporated by reference herein in its entirety. Despreaders 31 multiply the output of descrambler 30 with the spreading code for this particular mobile unit and integrate the output across a number of data chips equal to the spreading factor. Despreaders 31 desirably use a compact method of despreading, as fully disclosed in U.S. Patent Application Pub. No. 2007/0041433 A1, incorporated by reference herein in its entirety. Despreaders 31 also desirably employ buffer-based generation of Orthogonal Variable Spreading Factor (OVSF) code sequences, as fully disclosed in U.S. Patent Application Pub. No. 2007/006590 A1, incorporated by reference herein in its entirety. Symbol combiner 32 receives both (i) the output from channel estimator 29, which is the phase and amplitude distortion introduced by the channel, and (ii) the output from despreaders 31, which is an estimated symbol with channel distortion. Symbol combiner 32 multiplies the conjugate of the output of the channel estimator 29 with the output of despreaders 31. Symbol combiner also receives an estimated step size from enhanced-training block 34 to assist in improving accuracy of the data bits being provided to demapper 33. Demapper 33 uses a log-likelihood method to predict the most likely stream of data bits received from symbol combiner 32.

As discussed above, enhanced-training block 34 estimates step size and provides the estimated step size to error-calculation block 27 and to symbol combiner 32. In particular, enhanced-training block 34 uses additional CDMA physical channels (in addition to the common pilot, CPICH) to improve the training of the equalizer. These additional channels can include one or more of: the HSDPA control channels (HS-SCCH), broadcast channel (BCH), and user data channels (DPCH, F-DPCH). By using one of time-multiplexed logical equalizers EQ1, EQ2 of equalizer 15 to determine what data patterns were sent on these additional channels, the accuracy of equalizer training, and consequently receiver performance, can be significantly improved. For example, equalizer 15 could use one or more pilot reference signals to provide a first equalized signal, decode one or more predetermined data channels of the first equalized signal to recover an original data sequence for one or more of the data channels, and then use one or more recovered original data sequences as a reference signal, in combination with one or more pilot reference signals, to equalize the second received signal.

Power estimator block 35 is used to determine signal-to-noise ratios for the two RX-diversity channels being processed by EQ1 and EQ2, so that the processed symbols can be optimally combined and converted into log-likelihood ratios (LLRs).

Exemplary embodiments of reconfigurable equalizer 15 and post-equalizer 16 and their respective structural and functional components are fully described in U.S. Patent Application Pub. No. 2006/028229 A1, and U.S. Patent Application Pub. No. 2006/0291501 A1, incorporated herein by reference in their entirety.

Control block 17 provides control signals to the various components of AR 12 using synchronization, clock and reset signals from legacy R99 modem 21, and CPU instructions received via CPU interface 14.

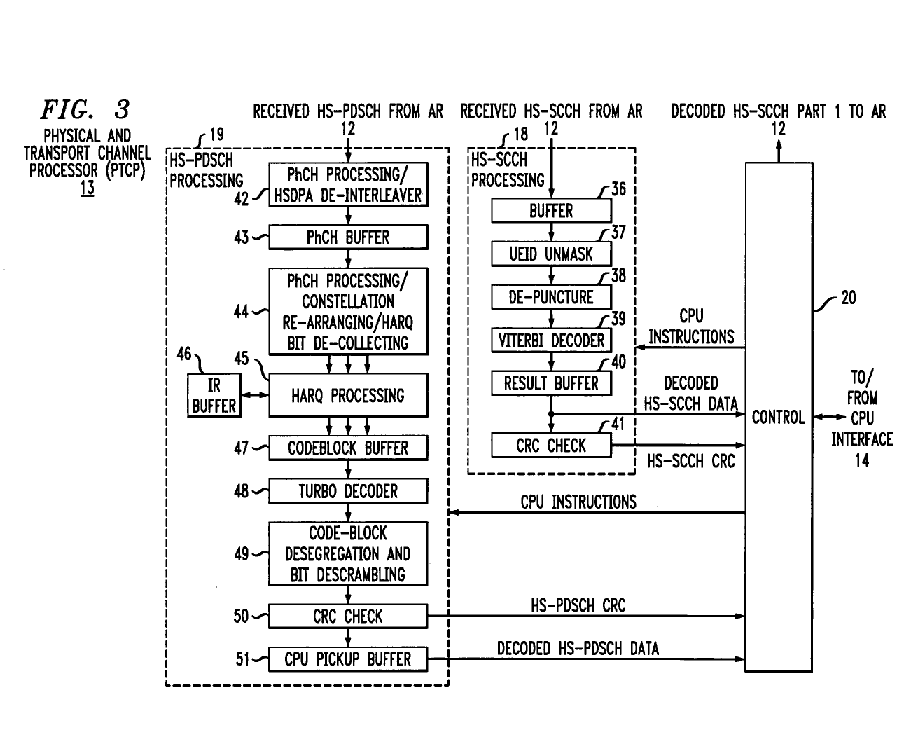

FIG. 3 illustrates the internal structure of PTCP 13, including HS-SCCH processing block 18, HS-PDSCH processing block 19, and control block 20.

Data arriving on the HS-SCCH physical channel signals the mobile terminal that HS-PDSCH data is about to arrive and includes channelization codes, modulation scheme, block size, HARQ process ID, redundancy, and constellation version needed to receive and decode the HS-PDSCH data. HS-SCCH processing block 18 receives the HS-SCCH data from AR 12 into buffer 36. Prior to transmission, the transmitting node scrambles the HS-SCCH data based upon the mobile terminal ID (UEID) so that only the intended mobile terminal can correctly decode or “unmask” it. Accordingly, HS-SCCH data is read from buffer 36 and provided to UEID unmask block 37 for UEID unmasking. The unmasked data is provided to de-puncture block 38 for depuncturing, and the depunctured data is provided for decoding to Viterbi decoder 39, which stores the decoded data in result buffer 40.

Up to four HS-SCCH channels can be monitored, and the correct one should be determined very quickly so that AR 12 can be configured to receive the correct HS-PDSCH channel. Although an HS-SCCH data block contains a cyclic-redundancy check (CRC) for error detection in a portion of the data block referred to as part-2 data, the channelization codes and modulation scheme parameters, called part-1 data, are first decoded and used before the CRC is received. Therefore, the HS-SCCH channel most likely intended for this particular mobile terminal is determined without the benefit of a CRC.

Viterbi decoder 39 decodes part-1 data it receives, and the result is provided to result buffer 40. In alternative embodiments, Viterbi decoder 39 (or a different block) re-encodes data it has decoded and compares each bit of the re-encoded data to a hard decision taken from the corresponding received symbol LLR. In this scenario, Viterbi decoder 39 forms a metric by summing the LLRs for which the re-encoded bits differ from the hard decisions, and Viterbi decoder 39 uses this metric to select, with good reliability, which HS-SCCH data block is most likely intended for this mobile terminal. Decoded part-1 data from this selected HS-SCCH data block is provided to result buffer 40. This decoded part-1 data is provided to control block 20, from which it is routed to AR 12.

Decoded part-1 data from result buffer 40 is provided to CRC-check block 41, which performs additional validation of this part-1 data by performing a CRC check against part-2 CRC data, once part-2 CRC data is available from the selected HS-SCCH channel. The CRC-check result is provided to the CPU via control block 20, and the CPU provides to HS-PDSCH processing block 19 instructions whether to receive or ignore data on the corresponding HS-PDSCH, based on the CRC determination of whether the selected HS-SCCH channel is actually intended for this particular mobile terminal.

Based on the CRC indication received from HS-SCCH processing block 18 via control block 20, the CPU instructs HS-PDSCH processing block 19 whether to process or ignore HS-PDSCH physical-channel (PhCH) data received from AR 12. Once HS-PDSCH processing block 19 identifies an HS-SCCH data block that appears to be intended for this particular mobile terminal, HS-PDSCH processing block 19 begins processing the HS-PDSCH PhCH data corresponding to the received HS-SCCH data block. Initial processing of the PhCH data is performed at PhCH processing/HSDPA de-interleaving block 42, which receives HS-PDSCH LLRs from AR 12 and performs de-interleaving as samples are written to PhCH buffer 43.

PhCH buffer 43 is a double buffer that stores blocks of HS-PDSCH data received from PhCH processing/HSDPA de-interleaving block 42. The size of buffer 43 depends on the HSDPA category. PhCH data read from buffer 43 is provided to PhCH processing/constellation re-arranging/HARQ-bit de-collecting block 44 for additional processing, including constellation re-arrangement (e.g., in the case of 16QAM modulation scheme) and HARQ bit de-collection from data read from PhCH buffer 43.

In conjunction with IR buffer 46, HARQ processing block 45 carries out Incremental-Redundancy (IR) combining. HARQ processing block 45 further performs HARQ rate de-matching (RDM) (stages 1 and 2) and HARQ-bit de-separation on data received from PhCH processing/constellation re-arranging/HARQ-bit de-collecting block 44. IR buffer 46 acts as a combining RAM and is disposed logically within HARQ processing block 45 between the two RDM stages. HARQ processing block 45 desirably implements a method of buffer compression (or “companding”) as fully disclosed in U.S. application Ser. No. 11/540,794, filed Sep. 29, 2006 as attorney docket no. Van den Beld 2-6, incorporated herein by reference its entirety.

The resulting blocks of processed data from HARQ processing block 45 are stored in codeblock buffer 47, from which this data is provided to turbo decoder 48.

Turbo decoder 48 is desirably a highly parallel implementation of a windowed log-MAP algorithm with a throughput of 1 bit per clock per half iteration, supporting 7.2 Mb/s with eight full turbo iterations at 122.88 MHz. Turbo decoder 48 features log-MAP decoding (with programmable look-up table), Hard-Decision Assist (HDA) early termination on half-iteration boundaries for power reduction, hardware turbo-interleaver address generator (with no software tables), and parameterized input sample width (e.g., 5 bits default) and window size (32 Turbo codewords default). The hardware turbo interleaver address generator, which requires no software input, predicts and performs training on possible pruned locations during the first half-iteration of each decoding operation and stores pruned locations in a compact lookup table. Thus, in subsequent half-iterations, turbo decoder 48 can perform on-the-fly pruneless interleaver address-generation without a duplication of logic. Exemplary embodiments of turbo decoder AQ are fully described in U.S. Patent Application Pub. No. 2006/0242476 A1, incorporated herein by reference in its entirety. Turbo decoded AQ also desirably employs a method in which normalization is not performed in the branch metric calculation, placing the normalization factor elsewhere in the calculations, to reduce memory requirements and to increase decoder sensitivity, as fully disclosed in U.S. Patent Application Pub. No. 2007/0050694 A1, incorporated herein by reference in its entirety.

Following turbo decoding, code-block desegregation and bit-descrambling block 49 performs concatenation of the turbo-decoded data, as well as removal of filler bits and bit de-scrambling. CRC-check block 50 performs CRC-checking of the output data from code-block desegregation and bit-descrambling block 49 as it is written into CPU-pickup buffer 51, from which it is read by the CPU via control block 20. CRC-check block 50 also provides the CRC-check result to the CPU via control block 20, which the CPU uses to determine whether to read or ignore the data in CPU-pickup buffer 51.

Control block 20 provides control signals to the various components of PTCP 13 using synchronization, clock and reset signals from legacy R99 modem 21, and CPU instructions received via CPU interface 14.

In a preferred embodiment, AR 12 is clocked at 61.44 MHz, and PTCP 13 runs synchronously with AR 12 at 61.44 MHz, except for turbo decoder 48, which has a clock rate determined by the supported HSDPA category, i.e., 61.44 MHz for Category 6, 122.88 MHz for Category 8, and 245.76 MHz for Category 10.

HSDPA co-processor 11 desirably uses a standard ASIC development flow in a 90 nm low-power CMOS process.

The architecture of HSDPA co-processor 11 is efficiently and easily scalable to all HSDPA data rates. When scaling to different HSDPA data rates in alternative embodiments, the principal design changes from the embodiments described and illustrated herein would be to the sizes of the memory buffers of PTCP 13.

Mobile terminal applications require low power consumption and low cost, in addition to HSDPA performance. In HSDPA co-processor 11, design size is kept to a minimum by reducing bit widths in the data path and memories wherever such reduced bit widths have no significant effect on performance. Power consumption can be minimized by techniques such as (i) using software-controlled and hardware-controlled gated clock zones, which allow circuitry to be turned off when not required, and (ii) one or more turbo decoder early termination techniques, as fully described in U.S. Patent Application Pub. No 2007/0033510 A1, incorporated herein by reference in its entirety.

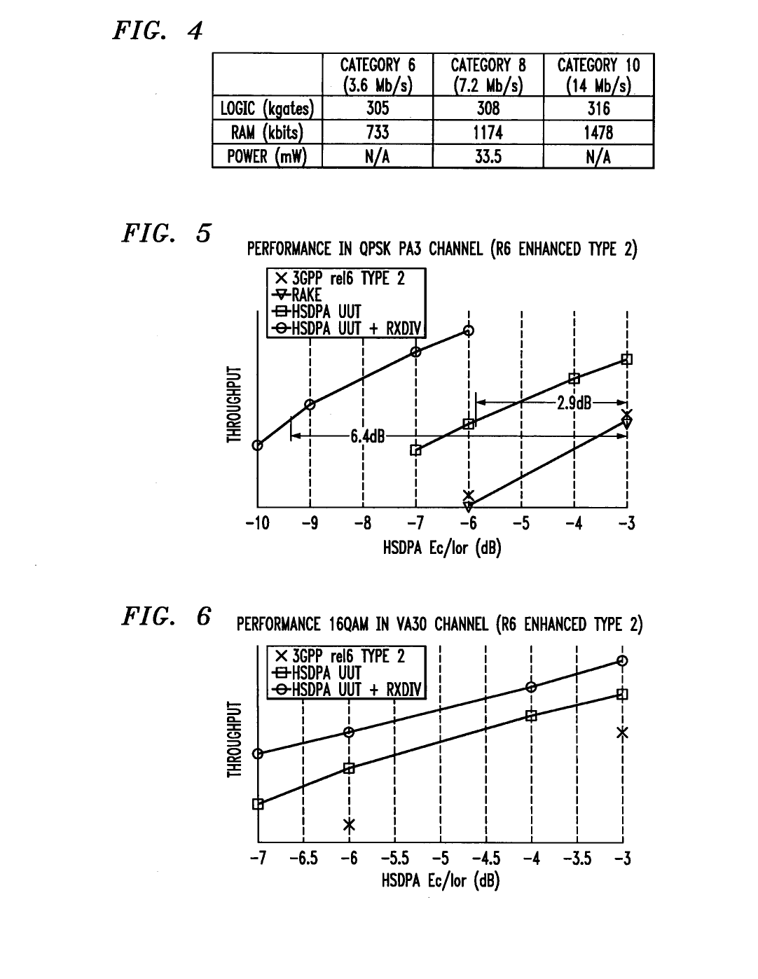

FIG. 4 is a table showing estimated size and peak power based on synthesis results for Category 8 during testing of co-processor 11. Gate and RAM estimates for Categories 6 and 10 illustrate how the architecture scales with data rate, i.e., as the HSDPA category number increases, more and more additional RAM is required for buffering and interleaving at the corresponding higher data rates.

FIG. 5 is a table showing 3GPP R6 Category 8 (7.2 Mb/s) throughput-performance simulations for the HSDPA co-processor 11 in a PA3 channel using QPSK modulation, and FIG. 6 is a table showing 3GPP R6 Category 8 (7.2 Mb/s) throughput-performance simulations for the HSDPA co-processor 11 in a VA30 channel using 16QAM modulation. As shown, performance exceeds that of a typical prior-art single-antenna rake receiver by 2.9 dB (with no RX diversity) and by 6.4 dB (with RX diversity). It is noted that the prior-art rake receiver cannot meet the difficult R6 3GPP Category-8 enhanced type-2 performance requirements shown, whereas the receiver employing co-processor 11 can meet these requirements.

Certain embodiments of the present invention desirably include one or more delay-compensation blocks for storing and processing signal samples or symbols at various processing stages, such that calculated channel parameters are synchronized to the data from which they were derived, as fully disclosed in U.S. application Ser. No. 11/311,003, filed Dec. 19, 2005 as attorney docket no. Banna 1-2-4-4-4, incorporated herein by reference its entirety.

Power-reduction methods may be employed for one or more portions of co-processor 11, as fully described in U.S. application Ser. No. 11/480,296, filed Jun. 30, 2006 as attorney docket no. Nicol 5-3-2, incorporated herein by reference its entirety. For example, power could be selectively provided to HS-PDSCH processing block 19 based on whether a control channel (monitored by HS-SCCH processing block 18) indicates that data is to be received.

With reference now to FIGS. 7-25, exemplary implementations of multiple logical equalizers of varying sizes will now be described.

Reference should now be had to FIG. 7, which depicts an exemplary communications circuit 100, in the form of a re-positionable equalizer receiver, in accordance with one aspect of the present invention. Circuit 100 can include a filter module 102, a control module 104, and an input buffer 106. In the exemplary embodiment depicted in FIG. 7, the filter module, control module, and input buffer are implemented on an integrated circuit chip 108. The filter module 102 can have a sampling window. The sampling window refers to a time span during which signal samples are gathered. Such samples can include, for example, data symbols or so-called “chips.” A “chip,” in this latter context, is intended to encompass a data symbol multiplied by, for example, a spreading code (e.g., when using Code Division Multiple Access (CDMA) techniques). In cases where standards such as 3GPP UMTS technical specification (TS) 25.211 are employed, the chip may have been further multiplied with a complex scrambling code, as described in 3GPP standard 25.213. It will be apparent from the context whether the term “chip” refers to an integrated circuit structure, or such a multiplied data symbol.

The control module 104 can have a ray parameter interface, such as register interface 110, that is configured to obtain information indicative of significant ray changes that render re-positioning of the sampling window desirable (of course, updates indicating no significant ray change can also be received). The control module 104 can be configured to determine repositioning parameters, in response to the information indicative of the significant ray changes. Such repositioning parameters can reflect the re-positioning of the sampling window.

The input buffer 106 can be configured to obtain samples of a received signal, such as Receiver In-Phase and Quadrature (RxIQ) samples. Input buffer 106 can be further configured to output received signal data, for example, in the form of an RxIQ array.

The filter module 102 can be coupled to the input buffer 106 to obtain the received signal data, and can also be coupled to the control module 104 to obtain the re-positioning parameters. The filter module 102 and the control module 104 can be configured to temporally re-position the sampling window in at least one of duration and location, in accordance with the re-positioning parameters, and to output a “filtered” or “cleaned” chip. Stated in another way, the sampling window is re-positioned in time by changing its duration (i.e. size) and/or location.

As will be discussed in greater detail below, in one or more exemplary embodiments of the present invention, the sampling window can be implemented in a filter having a number of taps, and can correspond to a span of the taps. The re-positioning parameters can include, for example, tap masking parameters specifying one or more of the filter taps that are to be masked, and/or can include parameters indicative of freezing or advancing a counter, such as a chip and/or slot counter, as discussed below.

In view of the foregoing discussion, it will be appreciated that in one or more embodiments of the present invention, the re-positioning parameters can include at least tap weights for the filter module 102, determined in accordance with tap masking parameters. The filter module 102 can be configured with a plurality of taps, to be discussed in greater detail below, and the sampling window can correspond to a tap span of the filter module 102. Re-positioning of the sampling window can be accomplished by applying a masking pattern (specified by the masking parameters, e.g.) to the plurality of taps in accordance with the aforementioned tap weights. The masking pattern can be substantially zero outside a desired location of the sampling window, and can be substantially one inside the desired location of the sampling window. As used herein, “substantially zero” means that the value of the mask is zero or approximately zero in most of the region outside the sampling window. While it is preferable that the value be zero in all locations outside the sampling window, one could envision, for example, a case with a single location or a few locations with a “one” value outside the sampling window; so long as these were not so many as to have a significant degrading effect on the masking function, such a case fits within the definition of “substantially zero.” Similarly, as used herein, “substantially one” means that the value of the mask is one or approximately one in most of the region within the sampling window. While it is preferable that the value be one in all locations within the sampling window, one could envision, for example, a case with a single location or a few locations with a “zero” value within the sampling window; so long as these were not so many as to have a significant degrading effect on the capture of significant rays, such a case fits within the definition of “substantially zero.”

The tap masking parameters can specify that the size of the sampling window is to be changed, that is, they can specify re-positioning at least the temporal duration of the sampling window (note that as used herein, “re-positioning” encompasses both changes in size and changes in location or both). Thus, it will be appreciated that the tap masking parameters could additionally, or alternatively, specify that the temporal location of the sampling window is to be re-positioned. As noted, the re-positioning parameters can include counter parameters that are indicative of counter freezing and/or counter advancing; such re-positioning parameters pertaining to counters can be provided in lieu of or in addition to the tap masking parameters discussed above, and can be used to change the location of the sampling window in time by freezing or advancing a counter. In one form of the invention, tap masking is employed to vary the size and/or location of the sampling window, while counter freezing and/or advancing are employed to change the location of the sampling window when significant rays fall outside of a physical tap span. The circuit 100 can include a parameter calculation block that is external to integrated circuit 108 and interfaces with control module 104 on integrated circuit 108 via register interface 110.

The filter module 102 can include, for example, a weight buffer 114 and a filter 116, such as a Finite Impulse Response (FIR) filter, coupled to the weight buffer. The weight buffer 114 can be coupled to the control module 104 to obtain the re-positioning parameters, and can be configured to provide tap weight data to the filter 116. The control module 104 can include an equalizer controller 118 coupled to the ray parameter interface (such as register interface 110) and to the input buffer 106. Control module 104 can further include a scrambling code generator 120 and a timing generator 122, each coupled to the ray parameter interface. Control module 104 can still further include a tap update logic module 124 that is coupled to the equalizer controller 118 and the scrambling code generator 120. The equalizer controller 118 can be configured to obtain the aforementioned information that is indicative of the significant ray changes, to determine the signal sample information, and to communicate the signal sample information to the input buffer 106. Further, the equalizer controller 118 can be configured to determine tap reset data and communicate the tap reset data to the tap update logic module 124.

In the exemplary embodiment depicted in FIG. 7, the information indicative of the significant ray changes includes the parameters NumChipsToAdjust, EqScramblingCodeOffset, and TapAdjustmentRequired. Pertinent parameters will be discussed further below. The signal sample information can include the parameters read_addr and write_addr. The tap reset data can include the parameter tap_reset. The scrambling code generator 120 can be configured to obtain the aforementioned information indicative of the significant ray changes, and to determine scrambling code data, such as the parameter scrambling_code, and to communicate such data to the tap update logic module 124. The timing generator 122 can be configured to obtain the aforementioned information indicative of the significant ray changes, and to determine counter parameters that are indicative of counter freezing and/or counter advancing. Such counter parameters can include chip_count and slot_count. The parameters discussed herein are exemplary and others could of course be employed. The tap update logic module 124 can be configured to obtain the aforementioned tap reset data and scrambling code data, determine updated weights in accordance with, e.g., the tap masking parameters for the masking pattern, and communicate the updated weights to the weight buffer 114 as per the aforementioned determining and obtaining of re-positioning parameters. The masking pattern can zero out undesired taps, and reset taps as required. As noted, the received signal samples input to buffer 106 and logic 124 can be RxIQ samples.

The control module 104 can have a sample input port configured to obtain samples of the received signal. In the exemplary embodiment depicted in FIG. 7, this is the location where the RxIQ_sample parameter is input to the tap update logic 124. Control module 104 can be configured to determine the aforementioned signal sample information, such as read_addr and write_addr, for example in the aforementioned equalizer controller 118. Thus, the input buffer 106 is coupled to the control module 104 and configured to obtain the signal sample information from the control module (as noted, in the exemplary embodiment of FIG. 7, from the equalizer controller 118 of control module 104). The input buffer outputs RxIQ_array to the filter module 102, for example, to the FIR filter 116. As noted, the aforementioned sampling window can be a tap span of the filter module 102. The received signal array data, RxIQ_array can have a length that is equal to the tap span.

Circuit 100 can also include an antenna module 126 that is configured to obtain received signal samples from a signal. Module 126 can include an antenna 128, an oscillator 130 and a block 132 for performing mixing and analog-to-digital conversion, as well as related functions. In general terms, module 126 includes antenna 128 and any appropriate downconversion circuitry for receiving radio frequency (RF) transmissions and transforming such received signals to baseband signals. Typically, oscillator 130 generates a waveform having a frequency identical to the carrier frequency. Such waveform is typically shifted and multiplied with the output of antenna 128 to generate in-phase and quadrature outputs. Such outputs may then be filtered to remove undesirable out-of-band frequency components. While modern receivers may typically not use intermediate stages producing intermediate frequency (IF) signals, use of such stages with one or more exemplary embodiments of the present invention is believed possible. Thus, module 126 can provide the aforementioned RxIQ samples to input buffer 106, and to control module 104 via tap update logic 124.

Circuit 100 can also include a microsearcher 134 coupled to the parameter calculation block 112 and configured to determine the ray position data and to supply such data to the parameter calculation block 112. Circuit 100 can further include a decoder module 136 that is coupled to the control module 104 (for example, to the timing generator 122) and to the filter module 102 (for example, to the filter 116). The decoder module 136 can be configured to obtain a cleaned or filtered chip designated as “cleaned_chip” from the filter 116 of filter module 102 and can be further configured to obtain counter parameters such as the aforementioned chi_count and slot_count from the control module. Such counter parameters, as noted, can be indicative of counter freezing and/or counter advancing, and can be determined, for example, by the timing generator 122.

The parameter calculation block 112 could be implemented, for example, by software running on a microprocessor or Digital Signal Processor (DSP) on another integrated circuit. The software could then write the appropriate parameters into the register interface 110, so that they can be read by blocks 118, 120, 122. The microsearcher 134 can be implemented, for example, in an application specific integrated circuit (ASIC) or DSP. The microsearcher 134 can provide ray positions to the parameter calculation block 112. The decoder module 136 can perform, for example, despreading and/or decoding functions, and can be implemented in an ASIC or DSP. The blocks on integrated circuit 108 can also be implemented in an ASIC or DSP.

The information indicative of the significant ray changes can include, for example, information indicative of a position of an earliest ray and/or information indicative of a position of a latest ray. As will be discussed below with regard to Priority 1 re-positioning, in one aspect of the present invention, the re-positioning of the sampling window can be conducted such that the earliest ray is located substantially centered in the sampling window. As will be discussed below with respect to Priority 2 repositioning, the information indicative of the significant ray changes can be generated so as to substantially center the sampling window at a point that is substantially equidistant between the earliest and latest rays. The parameter calculation block 112 can be configured to generate the aforementioned information indicative of significant ray changes so as to substantially capture the full impulse response of the earliest ray and/or the latest ray (preferably the full impulse response of both the earliest and latest rays).

By way of summary, it will be appreciated that due to different propagation paths, different versions of signals from a transmitter can arrive at a receiver at different times. For the sake of a simple example, a signal following a line of sight might arrive first, a signal reflecting once might arrive a short time later, and a signal that reflected twice might arrive a short time later still. The different versions of the signals that have traveled different paths are referred to as rays. As the receiver moves, because of a person walking or driving, for example, the paths, number of reflections, propagation times, and thus the rays change. The taps need to be far enough apart to encompass all, or at least most of, the significant rays. If a fixed tap span is used that is big enough to encompass all the significant rays, it will be too big in most cases and performance will suffer. Accordingly, techniques of the present invention can be employed to adjust the tap span to be just big enough, and properly positioned, so as to encompass all, or at least most, of the significant rays. That is, a re-positionable equalizer receiver according to an aspect of the present invention can realign the equalizer tap span when one or more of the significant rays moves outside the tap span. When this occurs, new parameters can be determined so that most of the significant rays are in the new span. The new parameters can be programmed into the equalizer hardware. The new parameters can include a number of chips to adjust and a scrambling code offset.

Still referring to FIG. 7, additional details of operation will be provided. It will be appreciated that communications circuit 100 is in the form of a re-positionable equalizer receiver, which receives digitized baseband samples (RxIQ_sample) from the antenna module 126. Ray positions are also received from microsearcher 134. Parameter calculation block 112 determines whether repositioning is necessary, and calculates an amount and direction of re-positioning needed. The re-positioning information is sent via the signals NumChipsToAdjust and EqScramblingCodeOffset, as well as by setting the TapAdjustmentRequired flag. Additional tables and figures will be presented and discussed below, summarizing the signals and flags. If tap span adjustment (i.e., repositioning) is required, the TapAdjustmentRequired flag will be asserted. Periodically, the equalizer controller 118, scrambling code generator 120, and timing generator 122 blocks check whether the TapAdjustmentRequired flag has been asserted. If it has, the equalizer must re-position the taps to the value of NumChipsToAdjust. If NumChipsToAdjust is negative, re-positioning is to the left, that is, earlier in time. Conversely, if NumChipsToAdjust is not negative, repositioning is to the right, that is, later in time. In either case, equalizer controller block 118 can reset all the tap weights by asserting the tap_reset signal.

The write_addr and read_addr parameters are supplied to input buffer 106 from equalizer controller 118. Buffer 106 uses write_addr to write a new value for RxIQ_sample into the buffer 106, and employs read_addr to read old values of RxIQ_sample to form the RxIQ_array, with the length of the array typically equal to the tap span for the FIR filter block 116. When the TapAdjustmentRequired flag is asserted, the scrambling code generator block 120 uses the new EqScramblingCodeOffset and NumChipsToAdjust to generate the scrambling code parameter to the tap update logic 124. Re-positioning to the left requires that the cell's primary scrambling code should be advanced by NumChipsToAdjust. As a result, NumChipsToAdjust worth of chips will be discarded for the current frame. Re-positioning to the right will typically require no changes to the cell's primary scrambling code, but the equalizer controller 118 and the scrambling code generator block 120 need to be idle for a period equal to NumChipsToAdjust worth of chips.

Tap update logic block 124 can employ an adaptive error updating algorithm, such as, for example, the NLMS algorithm, to calculate the tap weights and write the tap weights to the weight buffer block 114. Note that the calculation of the tap weights is essentially an estimate of the channel profile. The tap weights can then be read from the weight buffer block 114 and applied to the received samples in the FIR filter block 116. When the TapAdjustmentRequired flag is asserted, the timing generator block 122 can generate new counter signals chip_count and slot_count based on the value of NumChipsToAdjust. When advancing is done, the chip and slot counters jump ahead, by NumChipsToAdjust mod 2560 in the case of the chip counter and by NumChipsToAdjust/2560 in the case of the slot counter. When freezing is done, the chip and slot counters stay idle for corresponding numbers of chips.

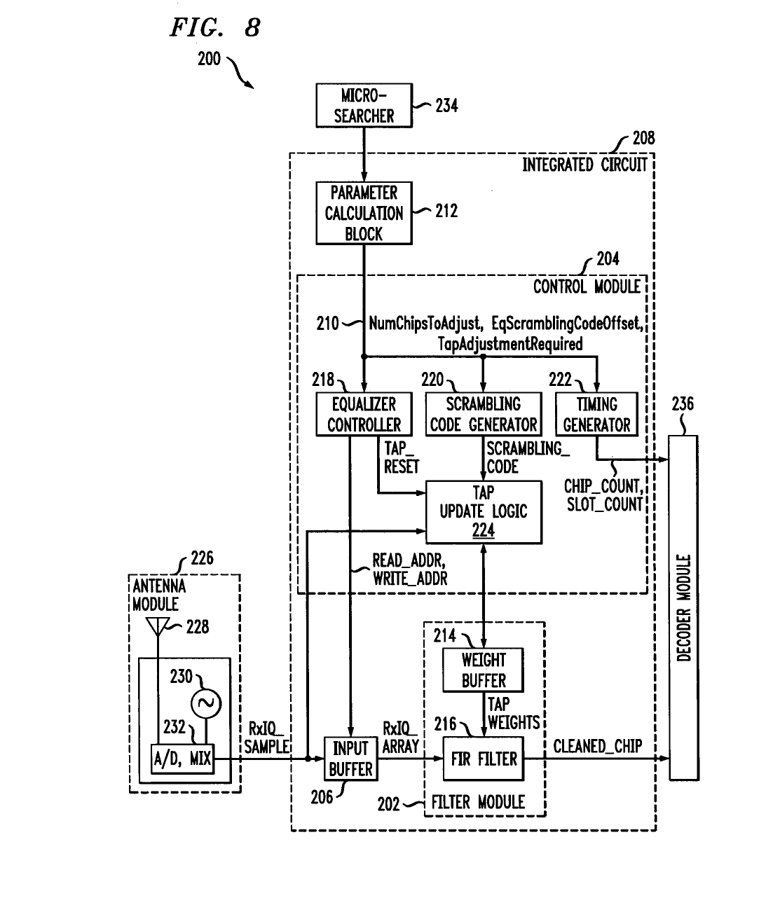

It will be appreciated that the circuit shown in FIG. 7 is exemplary, and other circuits employing techniques of the present invention are possible. By way of example and not limitation, one such circuit is shown in FIG. 8. Items in FIG. 8 that are similar to those in FIG. 7 have received the same reference character incremented by 100. As shown in the alternative embodiment of FIG. 8, parameter calculation block 212 is implemented on the same integrated circuit 208 as the control module 204, input buffer 206, and filter module 202. Since parameter calculation block 212 is on the same integrated circuit, the ray parameter interface is simply in the form of interconnections 210 on the integrated circuit 208, and a register interface such as 110 in FIG. 7 need not be employed. Functioning is otherwise similar to the circuit described with regard to FIG. 7. Of course, other alternative embodiments using the techniques of the present invention are also possible.

Further details will now be presented regarding one possible exemplary method by which the parameter calculation block 212 can determine values for parameters such as NumChipsToAdjust and EqScramblingCodeOffset. It should be noted that in comparison to the so-called RAKE receiver, where each “rake” finger is placed at the position of a significant ray, equalizer receivers typically require equalizer taps to span at least from the earliest to the latest significant ray. In order to adapt the equalizer receiver for practical use, appropriate techniques are required to keep track of the ray positions and to determine whether it is necessary to adjust the timing so as to re-position the equalizer taps when one or more significant rays fall outside of the current tap span. Table 1 below summarizes various parameters employed with respect to the description of the techniques of the present invention.

TABLE 1

| | |
|---|---|
| TapSpan | Maximum allocated equalizer Tap span. (TapSpanL and TapSpanR |
| | may each be set to TapSpan/2) |
| NumChipsToAdjust | Number of chips to re-position to equalizer tap. |
| EarliestRay | Absolute chip position of the earliest new ray (from microsearcher) |
| LatestRay | Absolute chip position of the latest new ray (from microsearcher) |
| EqScrambingCodeOffset | Represents the timing offset of the center of TapSpan, with respect |
| | to the frame boundary, in term of chips |
| RelativeEarliestRay | EarliestRay relative to the EqScramblingCodeOffset |
| RelativeLatestRay | LatestRay relative to the EqScramblingCodeOffset |

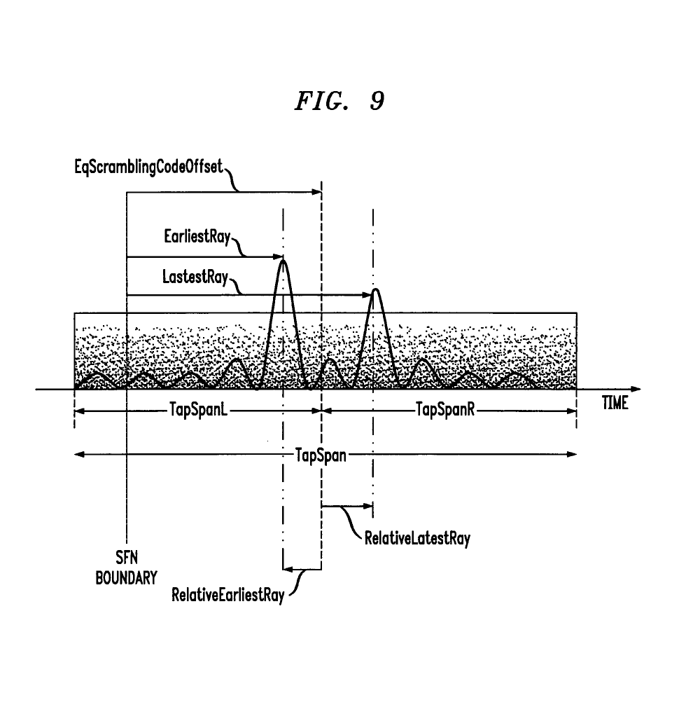

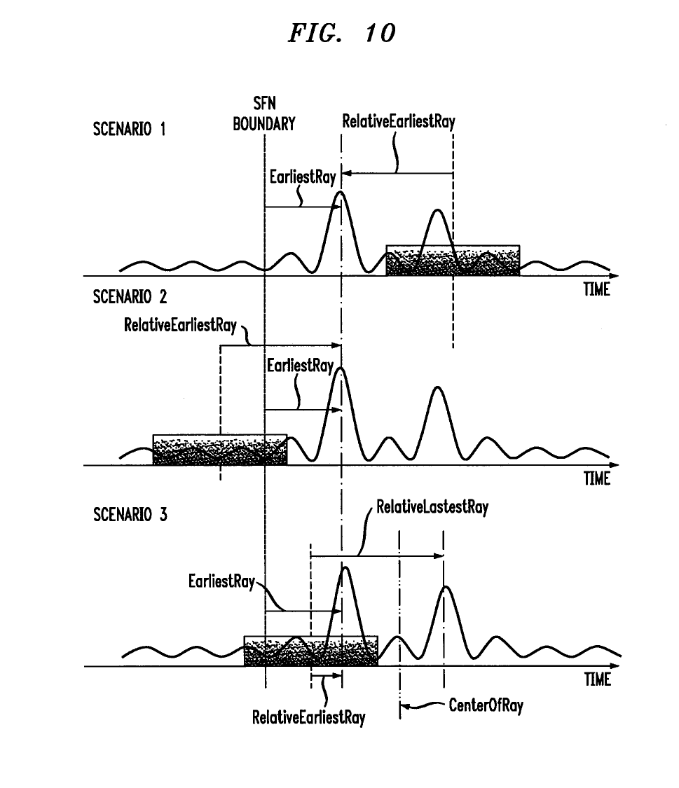

Pertinent parameters from Table 1 are illustrated in FIG. 9. Note that the SFN boundary refers to the Cell System Frame Number. For the base station (denoted in standard nomenclature as NodeB) the SFN boundary value represents the exact timing of the frame boundary for the transmitter. The SFN Boundary in FIG. 9 is essentially the NodeB SFN boundary in time. After going through the channel it produces the earliest and latest rays as shown.

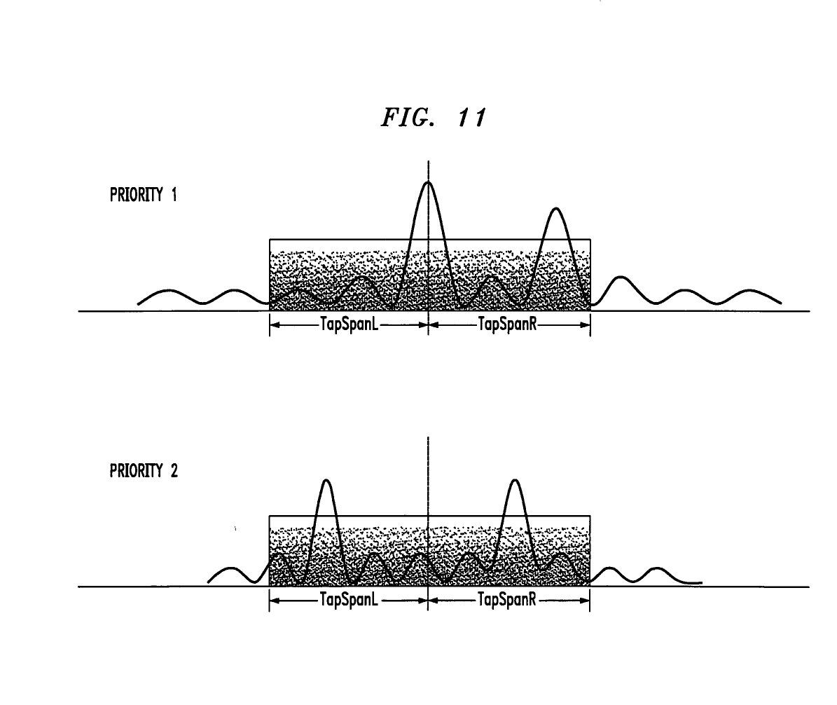

In one exemplary scheme employing techniques of the present invention, there are three scenarios where the equalizer embodied in IC 108 requires tap re-positioning. The three scenarios are illustrated with respect to FIG. 10. In Scenario 1, a significant ray falls outside of the equalizer tap span to the left In Scenario 2, a significant ray falls outside of the equalizer tap span to the right. In Scenario 3, the equalizer tap span is too small to cover both the earliest and latest significant rays.

When equalizer tap re-positioning is required, techniques of the present invention can employ a number of different possible schemes for tap re-positioning. Two such schemes, referred to as Priority 1 and Priority 2, are illustrated in FIG. 11. In the Priority 1 scheme, an effort is made to minimize any need for future tap re-positioning, by attempting to place the earliest ray in the center of the tap span. This allows room for any early rays to appear or drift within the region TapSpanL without requiring tap re-positioning. Accordingly, minimizing equalizer tap re-positioning is expected to have a positive effect on the performance of the equalizer.

In Priority 2 re-positioning, the center of the tap span is moved substantially to the mid-point between the earliest and latest rays, so that both rays are captured. This type of re-positioning is usually preferred if the distance between the earliest and latest rays is greater than the value of TapSpan/2 and less than TapSpan. If the distance between the earliest and latest rays is greater than TapSpan, Priority 2 re-positioning would normally be inappropriate and Priority 1 repositioning would be employed.

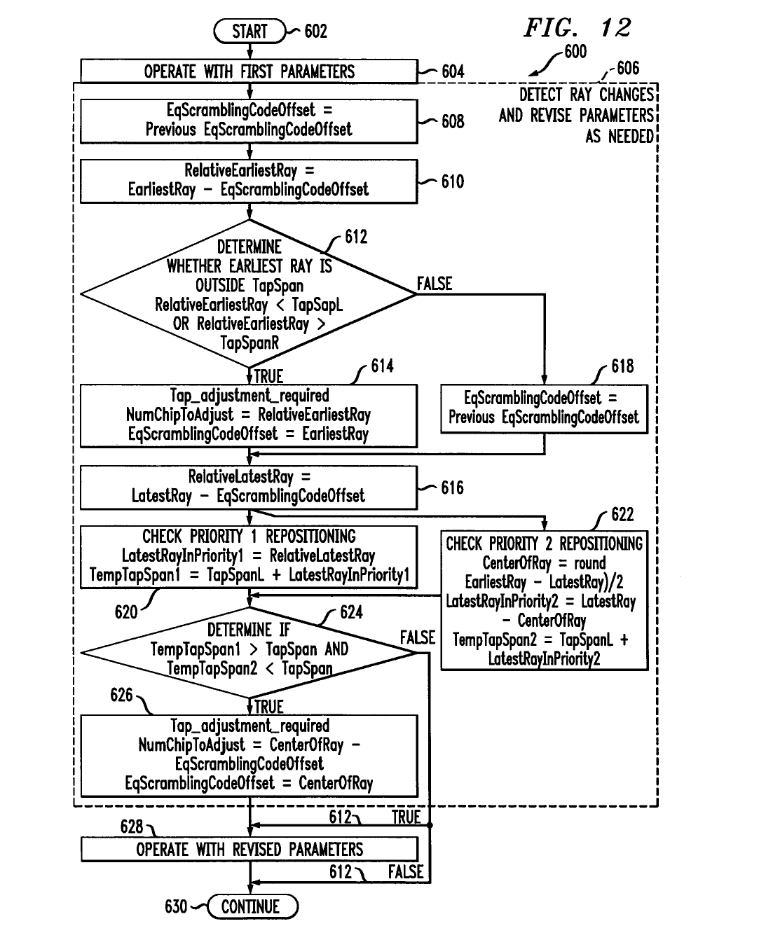

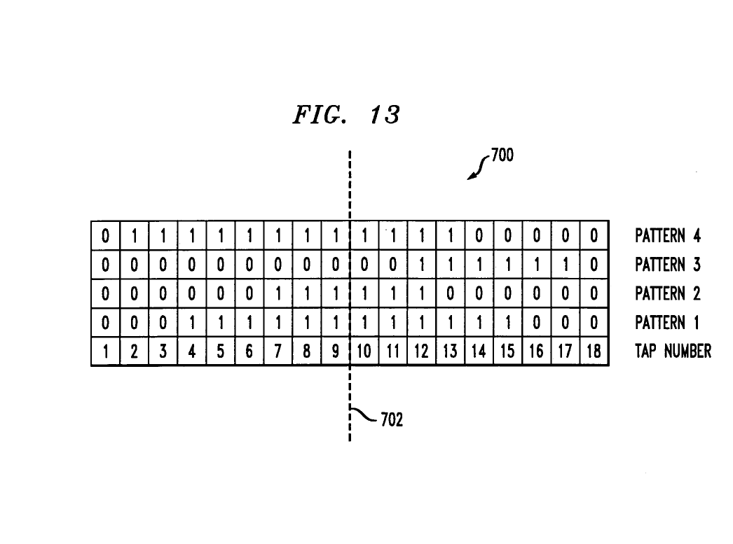

Periodically, microsearcher 134, 234 will provide an update of the significant ray findings, which can then be employed to determine whether tap re-positioning is required. If such is the case, then recalculation of parameters such as NumChipsToAdjust and EqScrambingCodeOffset is appropriate. Reference should now be had to FIG. 12, which depicts a flow chart 600 of method steps in a method of receiving a plurality of time-varying significant rays in a communications circuit. The method can be computer implemented (e.g., using ASICs, DSPs, or other techniques). As shown in FIG. 12, after beginning at block 602, the circuit can be operated with first parameters, such as first sampling span parameters indicative of a first sampling span, as shown at block 604. In block 606, changes in the plurality of rays can be detected. In block 628, operation can proceed with revised parameters. Such operation with revised parameters can be responsive to the changes detected in block 606. The revised parameters can be second sampling span parameters indicative of a second sampling span that is re-positioned temporally, in duration and/or location, with respect to the first sampling span. As will be discussed more fully below, if no substantial changes in the plurality of rays are detected, operation can continue with the original parameters. Furthermore, as indicated by the “continue” block 630, one can continue to loop through the flow chart of FIG. 12, by continuing to monitor for ray changes, and continuing to update the appropriate parameters when substantial or significant ray changes are detected.

The detection in block 606 can typically be directed towards determining whether one or more significant rays have moved outside the first sampling span. As discussed above with respect to the exemplary circuits, the first sampling span can be a first equalizer tap span associated with an equalizer filter, and the second sampling span can be a second equalizer tap span associated with the equalizer filter. The second sampling span parameters can be representative of an amount and/or a direction of re-positioning of the second equalizer tap span with regard to the first equalizer tap span indicated by the first sampling span parameters. As will be discussed more fully below, the second sampling span parameters can be indicative of a mask pattern. The mask pattern can have a number of right zeros, a number of left zeros, and a number of ones. The number of right zeros can be equal to a left tap span plus a relative latest ray position plus a tap guard distance, while the number of left zeros can be equal to the left tap span plus a relative earliest ray position, minus a tap offset distance.

Additional details will now be provided regarding one possible method of performing the detection in detecting step 606. In block 608, the parameter EqScramblingCodeOffset is set equal to the previous value of the EqScramblingCodeOffset. In block 610, a relative earliest ray position is calculated as the absolute earliest ray position minus the equalizer scrambling code offset. In block 612, a determination is made whether the relative earliest ray position is outside of the first sampling span. If such is the case, flow proceeds to block 614, where the tap adjustment required flag is set, the number of chips to adjust is calculated as equal to the relative earliest ray position, and a new equalizer scrambling code offset is calculated as equal to the absolute earliest ray position.

If it is determined in block 612 that the relative earliest ray position is not outside of the first sampling span, then in block 618, the equalizer scrambling code offset is set equal to the previous value of the equalizer scrambling code offset (or, thought of in another way, the value of the equalizer scrambling code offset remains unchanged from block 608). In any case, from blocks 614 and 618, processing can proceed to block 616, where the relative latest ray position is calculated as the absolute latest ray position less the equalizer scrambling code offset. In blocks 620 and 622, tentative re-positioning parameters can be determined, corresponding to a tentative sampling span, based on the relative earliest ray position and the relative latest ray position. In the specific example shown in FIG. 12, the tentative re-positioning parameters can correspond to checking of Priority 1 re-positioning, as in block 620, and Priority 2 re-positioning, as in block 622. More specifically, in block 620, a value for the latest ray in Priority 1 can be set equal to the relative latest ray position, and then a first temporary tap span can be calculated as the value of TapSpanL plus the latest ray in Priority 1. In block 622, a center of ray parameter can be calculated by rounding the difference between the earliest ray and the latest ray divided by 2, and the latest ray in Priority 2 can be set equal to the latest ray location less the center of ray parameter. A second temporary tap span can be calculated as equal to the value of TapSpanL plus the latest ray in Priority 2.

In block 624, a determination can be made whether the tentative re-positioning parameters indicate that both the earliest and latest ray will fit in the tentative sampling span. If the indicated relationships in block 624 are both true, then both the earliest and latest rays fit acceptably, and processing at block 626 can be carried out. That is, responsive to determining that the earliest and latest rays fit in the tentative sampling span, the second sampling span parameters can be set equal to the tentative re-positioning parameters. It will be appreciated that in block 626, the parameters calculated in block 614 are overwritten. If the relationship in block 624 is false, then one or both of the rays do not fit in the sampling span corresponding to the tentatively calculated parameters, and the relationships in block 614, or the original relationships, hold. That is, if block 612 was true, there was a change and the branch indicated by “612 TRUE” is followed such that operation proceeds at block 628 with the revised parameters calculated in block 614. Conversely, if block 612 was false, then the path through block 618 was followed, and there has been no change in the parameters, so that operation continues with the first parameters, as indicated by the “612 FALSE” branch.

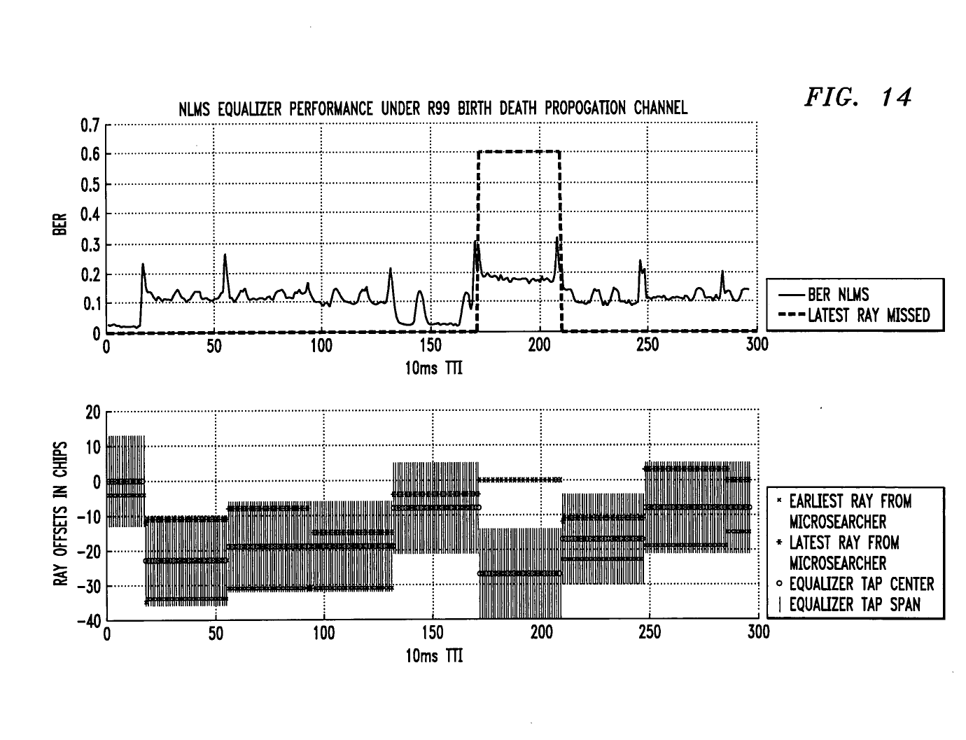

Attention should now be given to FIG. 13. By way of example, FIG. 13 shows a configuration 700 with 18 physical taps, that is, the parameter N_Taps is equal to 18. In pattern 1, taps 1-3 and 16-18 are masked. In pattern 2, taps 1-6 and 13-18 are masked. Thus, the size, but not the location of the sampling window has been changed in pattern 2 with respect to pattern 1. Note that the location is determined by the center of the sampling window. Both patterns 1 and 2 are centered about the dotted line 702. In pattern 3, taps 1-11 and 18 are masked. Thus, both the size and the location of the sampling window have changed with regard to pattern 1. In pattern 4, taps 1 and 14-18 are masked. Thus, the location but not the size of the window has changed with respect to pattern 1. It will be appreciated that masking refers to applying (e.g., by ANDing as discussed below with respect to FIG. 24) a value of zero (or substantially zero), in locations where significant rays are not expected, and applying a value of 1 (or substantially 1) in locations where significant rays are expected. It will be further appreciated that both the location and size of the sampling window can be moved within the parameters of the 18 physical taps. However, in some cases a significant ray might fall outside the 18 physical taps; in this case, the counter freezing or advancing discussed herein can be employed.

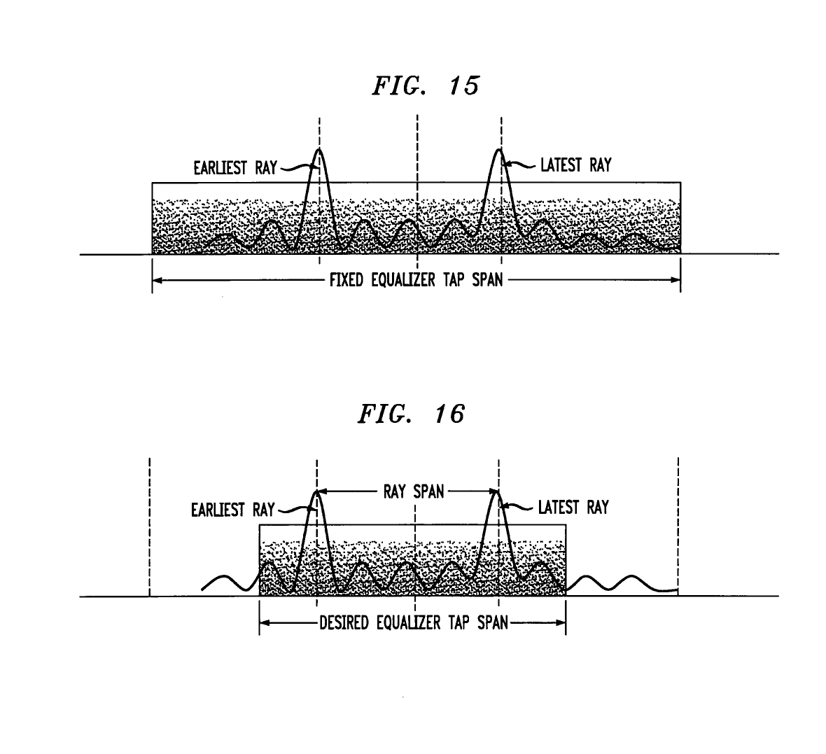

FIG. 14 depicts an exemplary application of the present invention to a 3GPP birth and death propagation condition, as specified in 3GPP TS 34.121, Radio Transmission and Reception (FDD) release 5. The figure depicts the tap span of the equalizer when the earliest and latest rays in the channel change constantly. As shown, the BER plot indicates that re-positioning helps the receiver maintain a BER of approximately 0.15. As can be seen, when the equalizer tap span is too short and cannot cover both the earliest and latest rays, the BER degrades as expected.

It will be appreciated that techniques of the present invention, as described herein, may offer one or more of the following advantages. The tap span can be of any desirable fixed size, the solution can be applied not merely on frame boundaries, but as frequently as desired or required (with the only limitation being the frequency of updates from the microsearcher). Furthermore, the techniques can reduce performance loss by positioning the rays within the equalizer tap span such as to minimize equalizer tap re-positioning. Techniques of the present invention can be employed with, for example, software routines that control advanced receivers, such as those that estimate the channel response of a receiver using an adaptive algorithm. In addition to the NLMS type receiver, a Minimum Mean Square Error (MMSE) receiver, or receivers using other techniques, can also be employed.

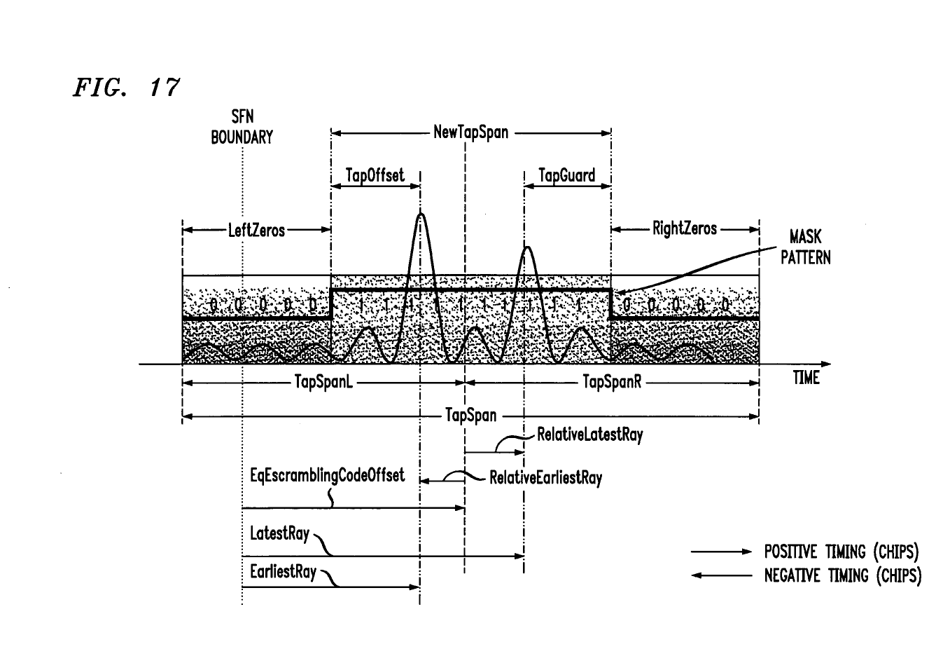

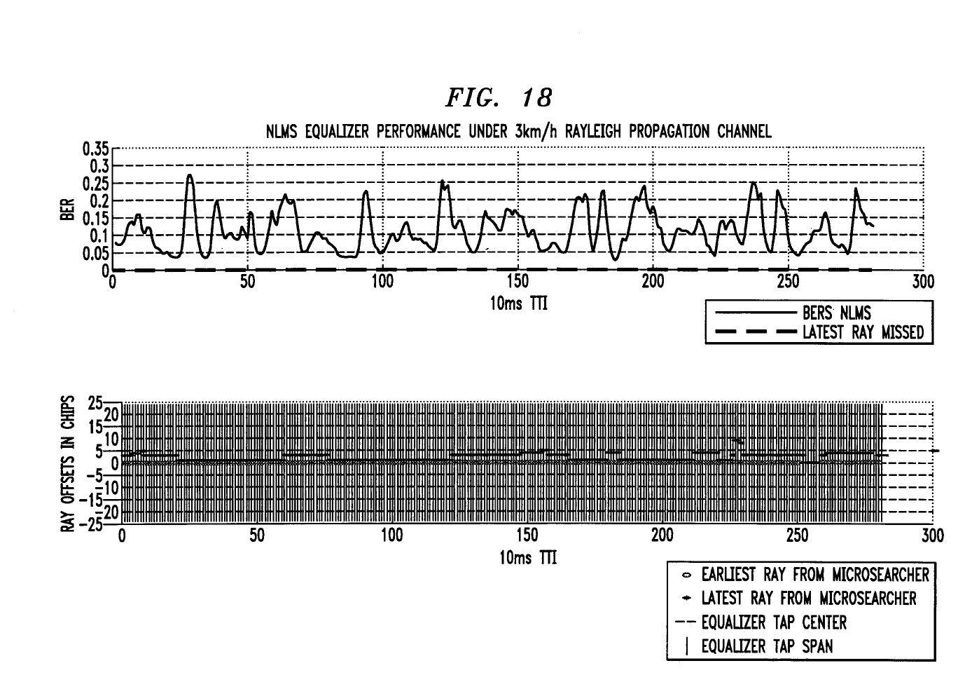

Further details will now be provided regarding one possible exemplary technique, in accordance with an aspect of the present invention, for calculating an appropriate equalizer tap span. The appropriate equalizer tap span can be determined dynamically, based on earliest and latest rays as determined from external hardware or software, such as the aforementioned microsearcher. A mask pattern, such as of ones and zeros as discussed with respect to FIG. 13, can be generated and deployed to vary the equalizer tap span. For illustrative purposes, a chip rate NLMS equalizer receiver is used to illustrate principles of the present invention. Such a receiver employs an adaptive error updating algorithm to calculate the tap weight, which is an estimate of the channel profile over a given window length (that is, tap span). The constantly updated tap weight is then applied to the received samples via FIR filtering to obtain “cleaned up” chips. Two criteria should be met in order to significantly enhance or maximize equalizer performance. First, as illustrated in FIG. 15, all or substantially all the significant rays detected by the microsearcher should be within the fixed equalizer tap span. Second, as depicted in FIG. 16, the tap span should not be excessively wide compared to the ray span. Accordingly, appropriate techniques have been developed to calculate the required tap span. Parameters employed in calculating the tap span are listed in Table 2 below, and are illustrated in FIG. 17. Parameters already listed in Table 1 are not repeated in Table 2.

TABLE 2

| | |
|---|---|
| NewTapSpan | Length of the tap span after the mask pattern |
| | is applied to the equalizer tap weights |
| TapOffset | Minimum distance from the beginning of the |
| | NewTapSpan to the EarliestRay |
| TapGuard | Minimum distance from the beginning of the |
| | LatestRay to the end of the NewTapSpan |
| LeftZeros | Amount of chips to shorten the TapSpan to the left |
| RightZeros | Amount of chips to shorten the TapSpan to the right |

FIG. 17 shows the interrelationship of the various parameters. The indicated techniques for calculating a revised mask pattern can be applied whenever new ray information becomes available, for example, from the microsearcher. The mask pattern can be generated given the two parameters RelativeLatestRay and RelativeEarliestRay. Values should be specified for TapOffset and TapGuard. These are done in a manner to permit the equalizer to capture the full impulse response of the earliest and latest rays. With a fixed tap span, and assuming for illustrative purposes that TapSpanL is ½ the length of TapSpan, the parameters can be calculated from the following equations:

RightZeros=TapSpanL+RelativeLatestRay+TapGuard (1)

LeftZeros=TapSpanL−TapOffset+RelativeEarliestRay (2)

MaskPattern=1, RightZeros<i>LeftZeros; 0, otherwise (3)

Where i=1 . . . TapSpan

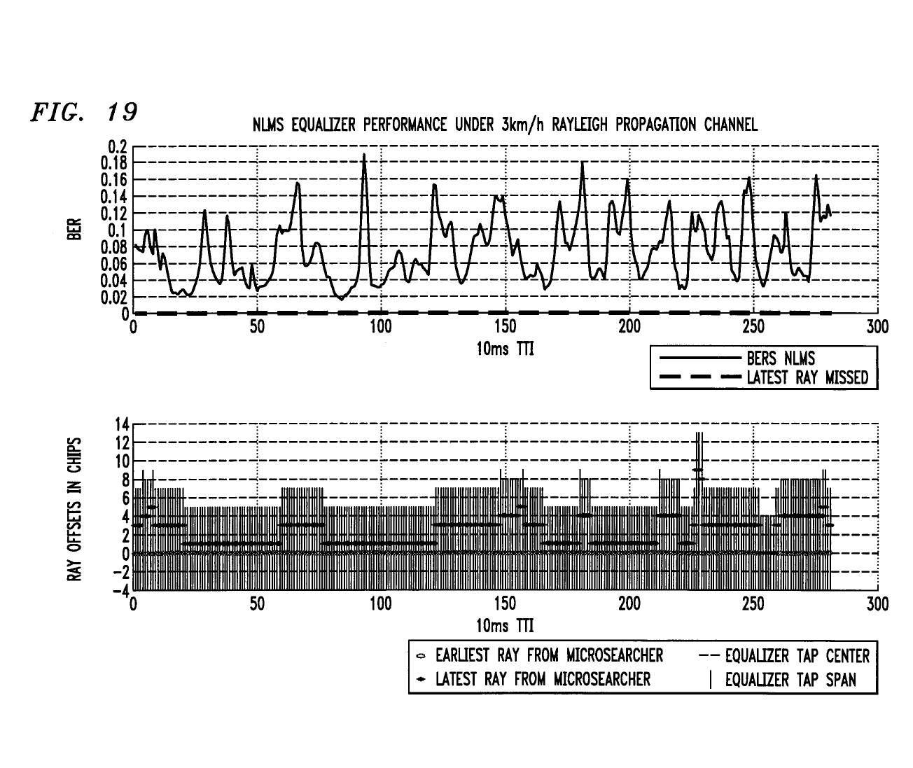

Note that RelativeEarliestRay and RelativeLatestRay can be positive or negative. In the positive case, the ray position is within TapSpanR; in the negative case, the ray position is within TapSpanL. FIG. 18 shows simulation results for the BER employing a fixed equalizer tap span, under conditions of a 3 km/h Rayleigh fading propagation channel. FIG. 19 shows a similar plot where the tap span is varied by applying the tap masking techniques of the present invention just discussed. In the example of FIG. 19, the tap span is 48 chips with a TapOffest and a TapGuard of 4 chips each. As shown in the figure, the tap span can be shortened or lengthened depending on the position of the latest rays.

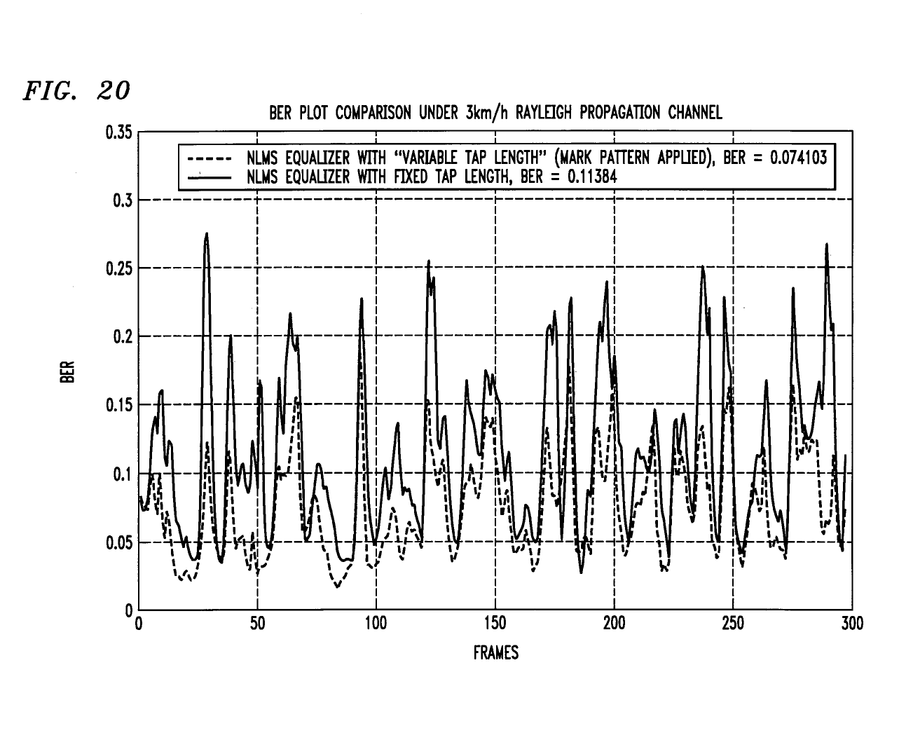

FIG. 20 depicts a BER comparison between the conditions in FIG. 18 and FIG. 19. The average BER over 299 frames is indicated in the legend. Without the use equalizer tap masking techniques of the present invention, approximately a 4.5 dB loss is noted. This is due to allowing the equalizer to estimate large portions of the channel where no significant rays exist. Thus, techniques of the present invention can result in enhanced or maximized performance of a receiver such as a chip rate NLMS equalizer receiver, and can also result in lower power consumption when the equalizer tap span is shortened, as fewer arithmetic operations are needed. Again, it should be noted that the present invention is applicable to a variety of adaptive equalizer receiver architectures.

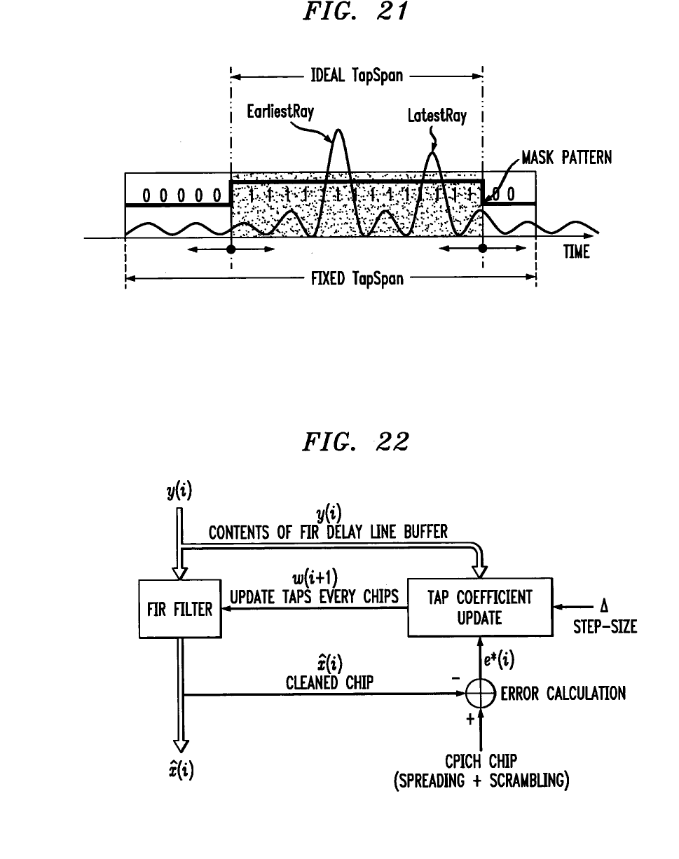

Additional details will now be presented regarding one exemplary method in which the tap masking techniques just described can be physically implemented. Tap masking can be realized by zeroing out the tap weights at the front and end sections of the equalizer span. Again, for illustrative purposes an NLMS equalizer receiver architecture is used, but is should be understood that other adaptive equalizers can be employed with techniques of the present invention. The tap mask pattern can be determined as discussed above. The application of the tap mask pattern to vary the span of the NLMS equalizer receiver will now be addressed. FIG. 21 depicts a masking pattern applied to the fixed tap span, resulting in the desired tap span referred to as “Ideal Tap Span.” FIG. 22 depicts the general architecture of a chip rate NLMS equalizer receiver having a fixed tap span. Such a receiver employs an adaptive error updating algorithm to determine tap weights. The tap weights, which estimate the channel condition, are applied to the received samples y(i) by FIR filtering. The output of the FIR filter becomes the “cleaned” chips \hat{x} (i) ready for descrambling and despreading. The script “R” refers to the real part of an expression and the Script “I” refers to the imaginary part of an expression. In the example depicted in FIG. 22, common pilot channel (CPICH) chips are employed.

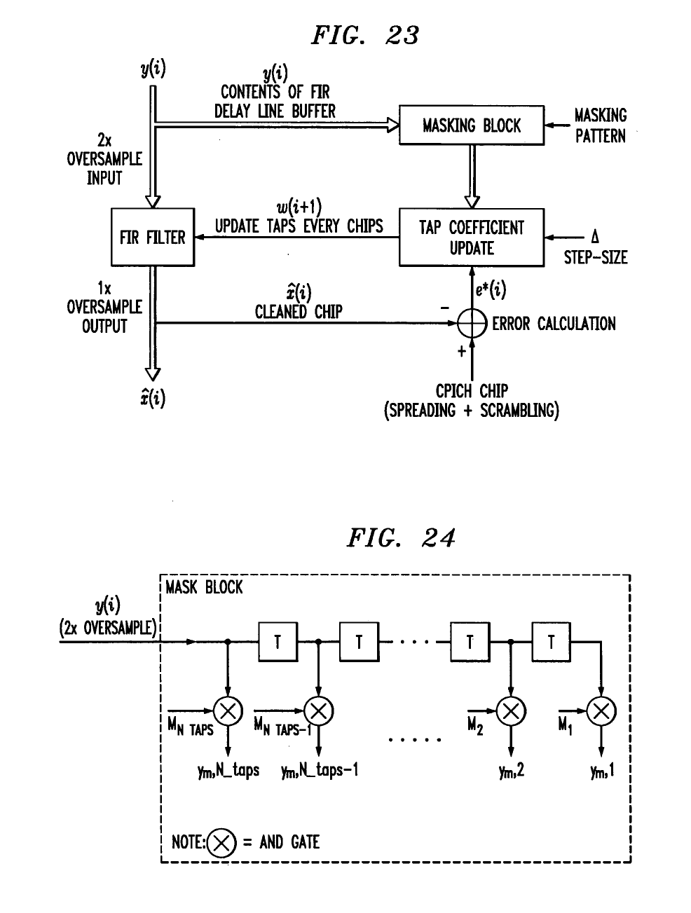

FIG. 23 depicts the NLMS receiver architecture with tap masking capabilities according to techniques of the present invention. A masking block is added to mask the content of the input buffer y(i) with the given mask pattern. FIG. 24 shows in detail the logic within the masking block. The mask pattern is a binary bit vector of Nₜₐₚₛ. The binary multiplication performed in the masking block is simply an “AND” operation, thus resulting in a design that is simple to implement and requires only a small amount of logic. Furthermore, the tap span can be readjusted without significant interruption in receiver operation.

With reference to FIGS. 26-33, the use of non-pilot reference channels to improve equalizer training and receiver performance will now be described. FIG. 26 shows a block diagram of one implementation of a prior-art receiver 2600 that uses a pilot channel to equalize (e.g., initialize (“train”) and track) a received signal. Receiver 2600 has upstream processing 2602, chip-rate normalized-least-mean-squares (NLMS) equalizer 2604, de-scrambler and de-spreader 2606, and downstream processing 2608. Upstream processing 2602 performs pre-equalization processing which might include analog-to-digital conversion, root raised-cosine filtering, or other processing to prepare a received signal for equalization. NLMS equalizer 2604 receives digital data y(i) from upstream processing 2602, equalizes signal y(i) to closely approximate the original pre-transmission signal, and outputs equalized signal \hat{x}(i) to de-scrambler and de-spreader 2606. De-scrambler and de-spreader 2606 removes the scrambling code and spreading sequences from equalized signal \hat{x}(i) and outputs soft symbols r(n). Soft symbols r(n) are then processed by downstream processing 2608, which might include symbol estimation, data symbol de-mapping, or other post-equalization processing for recovering one or more output data streams from the received signal.

NLMS equalizer 2604 equalizes digital signal y(i) using an update loop which comprises finite impulse response (FIR) filter 2610, coefficient updater 2612, and error calculator 2614. FIR filter 2610 receives incoming digital signal y(i), applies coefficients w(i) to signal y(i), and outputs equalized signal \hat{x}(i). Coefficients w(i) are calculated by coefficient updater 2612 using (1) incoming signal y(i) and (2) an error signal e(i) received from error calculator 2614. Error signal e(i) and coefficients w(i) are continuously updated at a maximum rate of one update per chip interval.

Coefficients w(i) may be calculated using any one of a number of approaches commonly known in the art. According to the embodiment of FIG. 26, coefficient updater 2612 receives signal y(i) and error signal e(i) and calculates new coefficients w(i+1) using a normalized-least-mean-squares (NLMS) approach. The NLMS approach is a variation of the least-mean-squares (LMS) approach, wherein each new coefficient w(i+1) is calculated as shown in Equation (1) below:

w_{LMS}(i+1)=w_{LMS}(i)−μ∇_{w}E[|e(i)²|], (1)

where ∇_{w} is the gradient of the expected value E[|e(i)|²] of error signal e(i), and μ the update step size.

The expected value E[|e(i)|²] (a.k.a., mean squared error (MSE)) can be represented as an “error performance surface.” A gradient descent approach is used to step across the surface to arrive at the minimum-mean-squared error (MMSE), which is represented by a local minimum on the surface. As the MSE of Equation (1) approaches the MMSE, the accuracy of tap weights w(i) increases. Substituting an instantaneous estimate for the expectation of Equation (1) yields the particular LMS calculation of Equation (2) as follows:

w_{LMS}(i+1)=w_{LMS}(i)−Δy(i)e*(i), (2)

where a small scalar is chosen as the step size Δ and e* (i) is the complex conjugate of error signal e(i). To obtain the NLMS coefficient w_{NLMS}(i+1), LMS Equation (2) is normalized to produce Equation (3) as follows:

$${w}_{NLMS} ( i + 1 ) = {w}_{NLMS} ( i ) - \tilde{Δ} \frac{y ( i ) {e}^{*} ( i )}{{‖ y ( i ) ‖}^{2}} . \qquad ( 3 )$$

As shown, new NLMS coefficient w_{NLMS}(i+1) uses a step size \tilde{Δ}, which reduces the complexity of tuning the step size.

The accuracy of NLMS equalizer 2604 in approximating the original pre-transmission signal is measured by error signal e(i). Thus, a smaller error e(i) represents improved equalizer performance. Error signal e(i) is obtained by comparing equalized output \hat{x}(i) of FIR filter 2610 to a reference signal x(i) as shown in Equation (4) below:

e(i)=\hat{x} (i)−x(i) (4)

Reference signal x(i) represents an expected value for the received signal, neglecting the effects of transmission. Thus, error signal e(i) decreases as equalized output \hat{x}(i) more closely approximates expected reference x(i) known by receiver 2600.

In typical transmissions, a large portion of the transmitted signal is not known by the receiver. However, a pilot signal z(i), which contains a known sequence of bits, may be transmitted for training and tracking purposes. Substituting pilot z(i) for reference x(i) in Equation (4) yields error signal e′(i) as shown in Equation (5):

e′(i)=z(i)−\hat{x} (i) (5)

The complex conjugate of error signal e′(i) may then be substituted for error e*(i) in Equation (3) to produce new NLMS coefficient w_{NLMS}(i+1).

In a 3_{rd} Generation Partnership Project (3GPP) application, receivers are equalized using the common pilot channel (CPICH). Furthermore, CPICH has a scrambled sequence c_{scram}(i) and a spread sequence c_{ch}(i) which are known by the receiver. For 3GPP Release 5 compatible receivers, either the primary pilot channel (PCPICH), the secondary pilot channel (SCPICH), or both may be used for continuous tracking and training. SCPICH has a spreading sequence and a scrambling code which are unique from PCPICH.

Pilot signal power in 3GGP and other applications is typically limited to 10 percent of the total transmission power. Since the pilot signal represents only a small portion of the total received signal power, signal error e′(i) never closely approximates zero. Additionally, since only pilot z(i) is used in calculating the gradient estimate, the unknown data symbols of input signal y(i) contribute to the gradient noise. In order to minimize error e′(i) and thus increase the performance of equalization, the pilot signal power can be increased. Increasing pilot signal power, however, reduces the amount of data that can be transmitted along with the pilot signal.

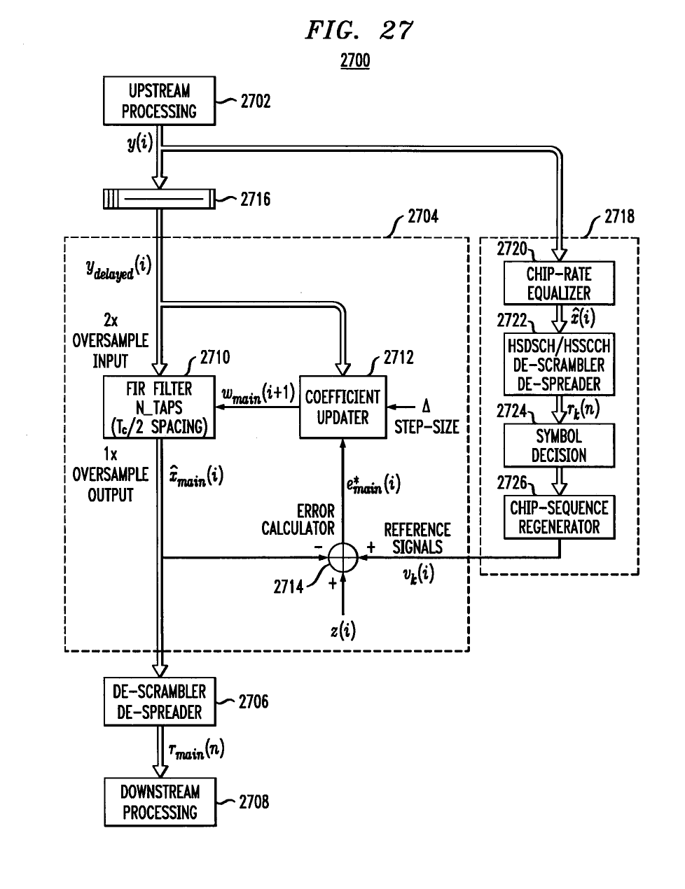

FIG. 27 shows a simplified block diagram of a receiver 2700 according to one embodiment of the present invention. Receiver 2700 is adapted to generate additional reference signals from received signals and use the additional reference signals to equalize the received signals. Receiver 2700 has upstream processing 2702, de-scrambler and de-spreader 2706, and downstream processing 2708, which are analogous to upstream processing 2602, de-scrambler and de-spreader 2606, and downstream processing 2608 of prior-art receiver 2600 of FIG. 26. Receiver 2700 also has reference generator 2718, main chip-rate normalized-least-mean-squares (NLMS) equalizer 2704, and input sample delay buffer 2716.

Reference generator 2718 has auxiliary NLMS chip-rate equalizer 2720, de-spreader and de-scrambler 2722, symbol decision block 2724, and chip-sequence regenerator 2726. Auxiliary NLMS equalizer 2720 receives digital signal y(i) from upstream processing 2702, equalizes signal y(i) in a manner similar to NLMS equalizer 2604 of prior-art receiver 2600 (i.e., using pilot channel z(i) as a reference), and outputs equalized signal \hat{x}(i). De-scrambler and de-spreader 2722 receives equalized signal \hat{x}(i), removes the scrambling code and spreading sequence from each channel k which is to be used as a reference, and outputs soft symbols rₖ(n) for each reference channel k. Symbol decision block 2724 then makes hard decisions on the soft symbols rₖ(n). The hard decisions are scrambled and spread by chip sequence regenerator 2726 using the original spreading sequence and scrambling code to form an additional reference vₖ(i) for each channel k. The one or more references vₖ(i) are then treated as known signals by main NLMS equalizer 2704 to equalize the received signals.

Input sample delay buffer 2716 delays received digital signal y(i) and transmits delayed signal y_{delayed}(i) to main NLMS equalizer 2704. Similar to prior-art NLMS equalizer 2604, main NLMS equalizer 2704 is an update loop comprising finite impulse response (FIR) filter 2710, coefficient updater 2712, and error calculator 2714. FIR filter 2710 receives delayed signal y_{delayed}(i), applies coefficients wₘₐᵢₙ(i) to signal y_{delayed}(i), and outputs equalized signal \hat{x}ₘₐᵢₙ(i). Coefficients wₘₐᵢₙ(i) are calculated by coefficient updater 2712 using (1) error signal eₘₐᵢₙ(i) received from error calculator 2714 and (2) delayed signal y_{delayed}(i). Error signal eₘₐᵢₙ(i) and tap weights wₘₐᵢₙ(i) are continuously updated at a maximum rate of one update per chip interval.

Error signal eₘₐᵢₙ(i) is calculated using pilot z(i) and one or more additional reference signals vₖ(i) generated from reference signal generator 2718. Equation (4) is modified to produce main error signal eₘₐᵢₙ(i) as shown below:

eₘₐᵢₙ(i)=z(i)+vₖ(i)−\hat{x}ₘₐᵢₙ(i) (6)

Note that, depending on the channels used as additional references, the additional reference signals vₖ(i) might be weighted.

New tap weights wₘₐᵢₙ(i+1) are then calculated using main error signal eₘₐᵢₙ(i) and delayed incoming signal y_{delayed}(i) by modifying Equation (3) as shown in Equation (7):

$${w}_{main} ( i + 1 ) = {w}_{main} ( i ) - \tilde{Δ} \frac{{y}_{delayed} ( i ) {e}_{main}^{*} ( i )}{{‖ {y}_{delayed} ( i ) ‖}^{2}} \qquad ( 7 )$$

After equalization, the spreading sequences and scrambling codes are removed by de-scrambler and de-spreader 2706 from equalized signal \hat{x}ₘₐᵢₙ(i) to obtain soft symbols rₘₐᵢₙ(n), which are further processed by downstream processing 2708.

By adding one or more additional reference signals vₖ(i) to the error calculation, error signal eₘₐᵢₙ(i) may more closely approximate zero than error signal e′(i) of prior-art receiver 2600. This more-accurate error calculation improves the training and tracking performance of receiver 2700 over prior-art receiver 2600 when using the same step size \tilde{Δ}. Furthermore, since training and tracking is more accurate, throughput of the equalizer can also be increased.

By maintaining the pilot power and using additional reference signals as described above, the effective power available for training and tracking can be increased without reducing the amount of transmitted data. This increase in power improves the performance of the receiver by decreasing the bit error rate, and therefore, increases the overall throughput of the receiver. On the other hand, the pilot power can be decreased while using additional reference signals for training and tracking, where the decrease in pilot power permits more data to be transmitted while the receiver maintains a bit error rate that is the same as the prior-art receiver. Other implementations can achieve both decreased bit error rate and increased data transmission rate by only partially reducing the pilot power.

This invention may be used in various applications in which a receiver equalizes a data signal using one or more pilot channels. An example of one such application is a high-speed downlink packet access (HSDPA) transmission to a 3GPP receiver. In an HSDPA transmission, the channels which may be used to generate additional reference signals include the one to four high-speed shared control channels (HSSCCHs), the primary common physical channel (PCCPCH), the high-speed shared data channel (HSPDSCH), and the downlink physical channel (DPCH).

At least one of the HSSCCH channels will be present during an HSDPA transmission. As described above, de-scrambler and de-spreader 2722 receives equalized signal \hat{x}(i), removes the scrambling code and spreading sequence from each HSSCCH channel k (e.g., where k=1 to 4), and outputs soft symbols rₖn) for each channel k. Note that each of the HSSCCH channels is coded with a relatively high spreading factor (e.g., approximately 128 chips/symbol). Consequently, symbol decision block 2724 can make an accurate hard decision on each soft symbol rₖ(n) independently. This process occurs over a period of one symbol, and thus, main equalizer 2704 can operate using a delay of as little as 128 chips. Chip sequence regenerator 2726 then scrambles and spreads the hard decisions for each channel k using the original spreading sequence and scrambling code of each channel k to form each additional reference signal vₖ(i).

The PCCPCH channel is transmitted during the remaining 90 percent of the slot when the SCH channel is not transmitted. An additional reference signal may be generated from PCCPCH in a manner similar to the method used above for the HSSCCH channels. PCCPCH has a relatively large spreading sequence (i.e., 256 chips/symbol). Consequently, accurate hard decisions may be made on each PCCPCH soft symbol independently, and main equalizer 2704 can operate using a delay of as little as 256 chips.

HSPDSCH has a relatively small spreading sequence (i.e., approximately 16 chips/symbol). Due to the small spreading sequence, symbol decision block 2724 might not be able to make an accurate hard decision on each soft symbol rₖ(n) independently. Instead, symbol decision block 2724 receives a number of symbols and performs a cyclic redundancy check. If there is no error among the symbols, then symbol decision block 2724 makes a hard decision on each symbol. Note that this process takes more than one transmission time interval (TTI), and thus, main equalizer 2704 operates using a delay of over one TTI. The symbols are then scrambled and spread by chip sequence regenerator 2726 using the original channel spreading factor and scrambling code to form the additional reference vₖ(i).

DPCH has a spreading sequence which may change at various times. Performance of the channel will be best at times when the channel has a relatively high spreading sequence. In this case, an additional reference may be generated in a manner similar to the method used for the HSSCCH channels.

In addition to the improvements gained by using additional reference signals, further improvements in the throughput of the receiver can be achieved by selecting an optimum step size for use by the coefficient updater of the main equalizer.

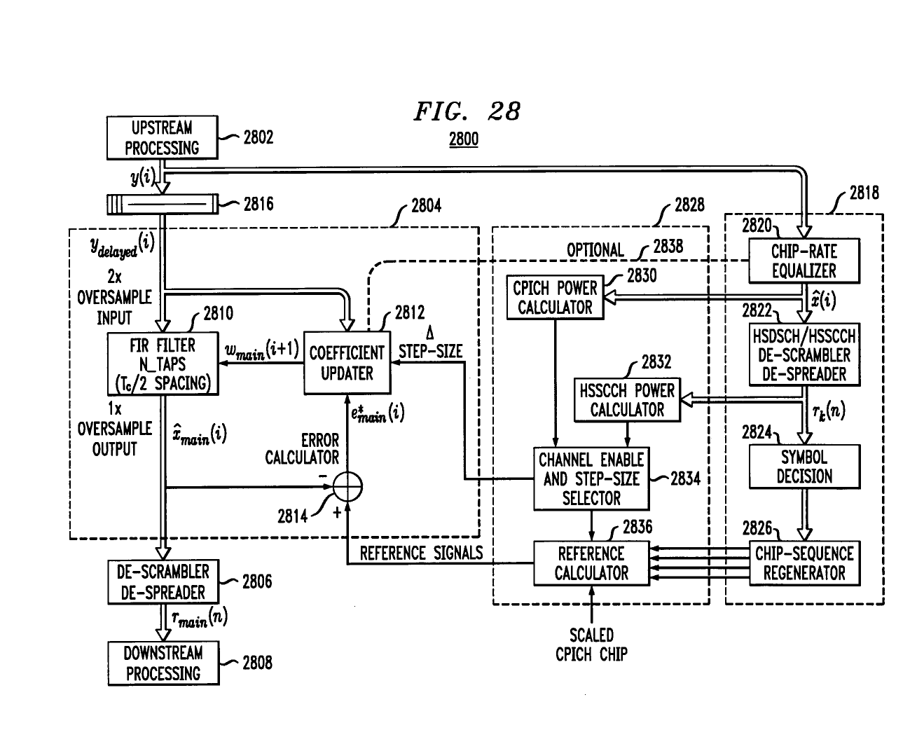

FIG. 28 shows a simplified block diagram of a receiver 2800 according to one embodiment of the present invention that generates one or more additional reference signals and selects an optimum step size \tilde{Δ} from a look-up table based on the number of additional references available and the power of those references. Receiver 2800 has upstream processing 2802, input sample delay buffer 2816, main chip-rate normalized-least-mean-squares (NLMS) equalizer 2804, de-scrambler and de-spreader 2806, downstream processing 2808, and reference generator 2818, which perform operations analogous to those of the corresponding elements of receiver 2700 of FIG. 27. In addition, receiver 2800 has step-size generator 2828. For ease of discussion, the following assumes that receiver 2800 has been designed for training and tracking using all four HSSCCH channels.

Step-size generator 2828 has CPICH power calculator 2830, HSSCCH channel power calculator 2832, channel enable and step-size selector 2834, and reference calculator 2836. CPICH power calculator 2830 receives equalized signal x(i) and calculates the total CPICH symbol power of the equalized signal over a given chip period using Equations (8) and (9) as follows:

$$\begin{matrix}{Cpich\_Symbol}_{512} ( n ) = {\sum }_{i = 1}^{512} z ( i ) * \hat{x} ( i ) & ( 8 ) \\ Cpich\_Power ( n ) = {( Re [ {CPICH\_ Symbol}_{512} ( n ) ] )}^{2} + {( Im [ {CPICH\_ Symbol}_{512} ( n ) ] )}^{2} & ( 9 )\end{matrix}$$

In Equations (8) and (9), a chip period of 512 chips is shown based on the reception of a transmit-diverse signal in which a complete pilot sequence comprises two CPICH symbols of 256 chips. This period may vary depending on the implementation. For example, a non-transmit diverse reception may have a period other than 512 chips such as a period of 256 chips. CPICH_Power(n) may then be low-pass filtered.

HSSCCH power calculator 2832 receives de-scrambled and de-spread symbols rₖ(n) for each channel k and calculates the symbol power of each HSSCCH channel k for a maximum of one TTI. In this embodiment, where there are 128 chips per symbol, the power is calculated as shown in Equations (10) and (11):

$$\begin{matrix}{r}_{k} ( n ) = {\sum }_{i = 1}^{128} ( {r}_{k} ( i ) ) & ( 10 ) \\ Hsscch\_Power {\_ Sum}_{k} ( n ) = {\sum }_{n = 1}^{N} [ {( Re [ {r}_{k} ( n ) ] )}^{2} + {( Im [ {r}_{k} ( n ) ] )}^{2} ] , & ( 11 )\end{matrix}$$

where N is the number of symbols used to generate the power of Equation (11) as shown in Equation (12):

Hsscch_Power_{—}Nrₖ(n)=N (12)

In one possible embodiment, only one symbol is used in the power calculation, such that N is equal to one. In other embodiments, the number N of symbols used to generate the power of Equation (11) may be greater than one. For example, the power of Equation (11) may be calculated for a transmission-time interval (TTI), which is 7680 chips in length and has 128 chips per symbol. In this case, the number N would be incremented by 1 after every 128 chips until Nis equal to 60 (i.e., 7680/128=60). At the beginning of the next TTI, N would be reset to 0.

Channel enable and step-size selector 2834 receives the calculations from CPICH power calculator 2830 and HSSCCH power calculator 2832 for each HSSCCH channel k. These calculations are then used to detect which channels are available for training and tracking. Based on the number of channels available and the power of each channel, channel enable and step-size selector 2834 identifies an index number that is used to retrieve an optimum step size from a look-up table. This process may be performed through sequential steps of pseudocode.

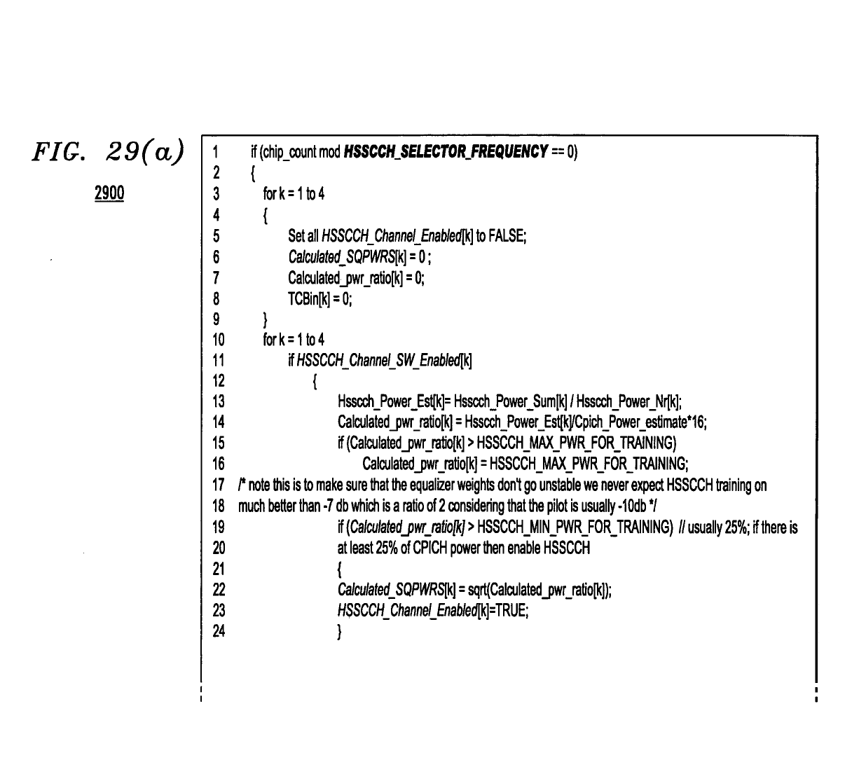

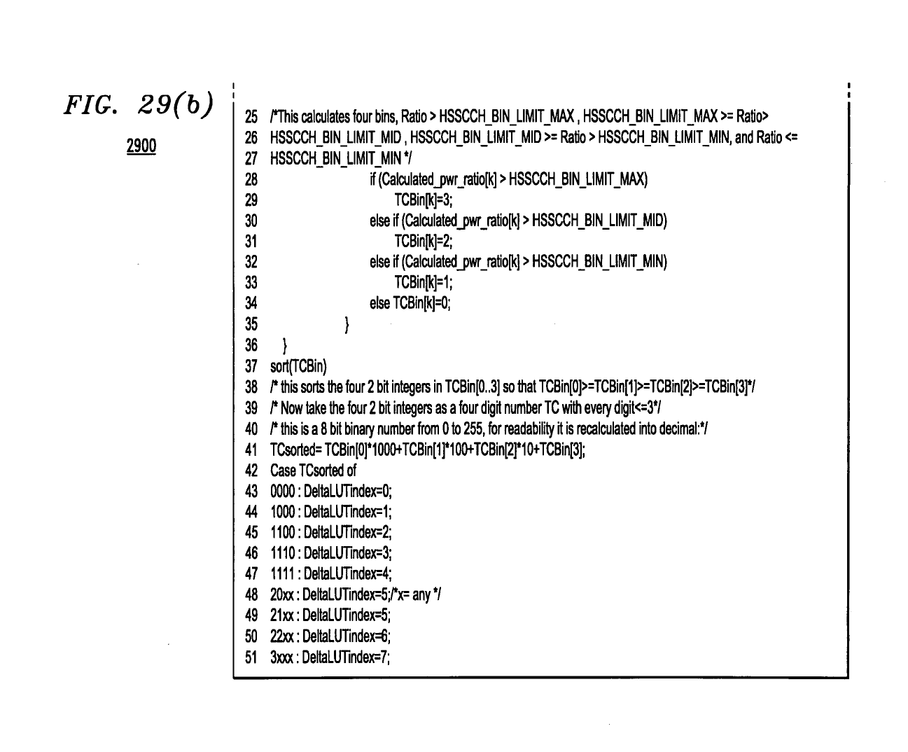

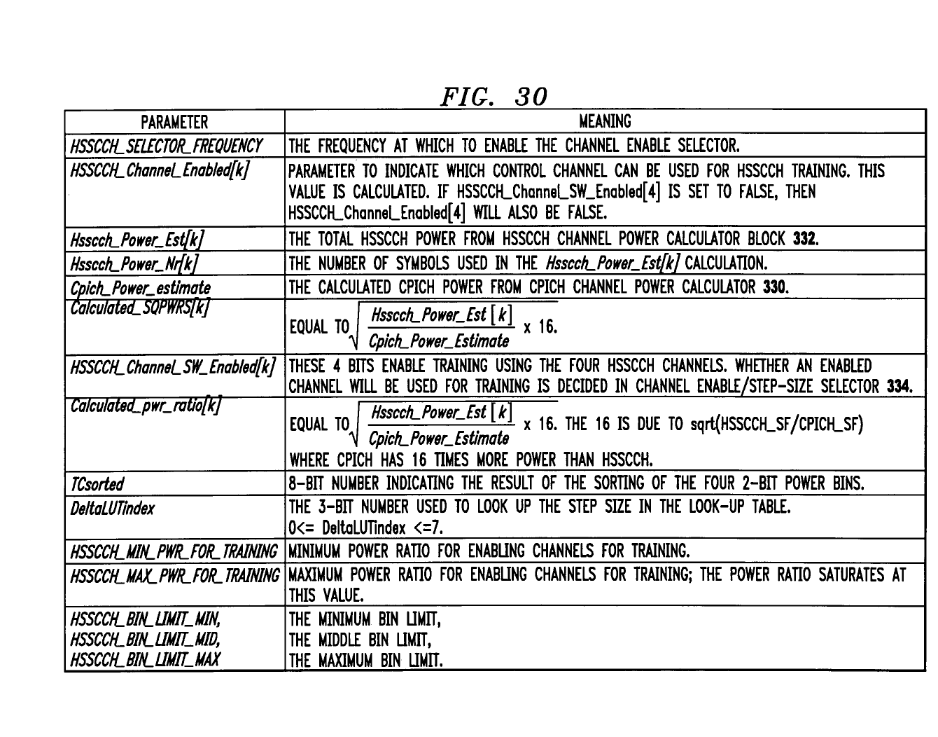

FIGS. 29(a) and (b) show one implementation of pseudocode 2900 that implements functions of channel enable and step-size selector 2834 of FIG. 28. FIG. 30 shows a table of parameters for pseudocode 2900 of FIGS. 29(a) and (b). In line 1 of pseudocode 2900, the chip_count is compared to a predetermined frequency HSSCCH_SELECTOR_FREQUENCY. In one possible implementation, HSSCCH_SELECTOR_FREQUENCY is selected to be 128 chips. At every 128 chips, pseudocode 2900 resets the values calculated for the four HSSCCH channels during the previous iteration as shown in lines 3 through 9 of FIG. 29(a).

At line 11, pseudocode 2900 uses information received from higher layers to determine which of the HSSCCH channels are present. For each channel that may be present, channel enable and step-size selector 2834 receives an HSSCCH_Channel_SW_Enabled[k] signal. Pseudocode 2900 then determines which of the four HSSCCH channels has sufficient power for use as additional reference signals (lines 10 through 24). Those channels which have sufficient power are then enabled. In particular, in line 13 of pseudocode 2900, the average power for each HSSCCH channel (Hsscch_Power_Est[k]) is calculated by dividing the corresponding calculated HSSCCH power (Hsscch_Power_Sum[k]) by the total number of symbols (Hsscch_Power_Nrₖ(n)) used for the power calculation. Each average power is then used to calculate a power ratio (Calculated_pwr_{—l ratio[k]) for each channel k as shown in line 14.}

The power ratio for each channel k is compared to predetermined thresholds for the maximum power ratio (HSSCCH_MAX_PWR_FOR_TRAINING) and the minimum power ratio (HSSCCH_MIN_PWR_FOR_TRAINING) (lines 15 through 20). If the power ratio for a channel k is greater than the maximum threshold, then pseudocode 2900 sets the power ratio for that channel equal to the maximum threshold. Then, for each channel k whose power ratio is greater than the minimum threshold but less than or equal to the maximum threshold, pseudocode 2900 calculates the square root of the power ratio (Calculated_SQPWRS[k]) and sets the enable signal (HSSCCH_Channel_Enabled[k]) to true (lines 22 and 23, respectively). Any channel k whose power ratio is below the minimum power ratio threshold is not enabled (i.e., will not be used to generate an additional reference signal).

Note that in alternative embodiments of the present invention, pseudocode 2900 may generate a power value other than the power ratio described above. Furthermore, pseudocode 2900 may determine if this other power value satisfies a power-threshold condition other than the minimum threshold described above. For example, pseudocode 2900 might calculate a power value in which the CPICH power is divided by the HSSCCH power (i.e., Cpich_Power_estimate/Hsscch_Power_Est[k]). In this example, an HSSCCH channel satisfies the power-threshold condition when the HSSCCH channel's power value is less than a maximum threshold. Other implementations are possible within the scope of this invention.

Next, pseudocode 2900 designates each channel k as a high-power, medium-power, low-power, or very low-power channel, by associating each channel to a two-bit bin number (TCBin[k]=0, 1, 2, 3) (lines 25 through 34). A high-power channel has a power ratio greater than a predetermined maximum-power ratio (HSSCCH_{—l BIN}_LIMIT_MAX) and is assigned a two-bit bin number equal to 3 (lines 28 through 29). A medium-power channel has a power ratio that is greater than a predetermined middle-power ratio (HSSCCH_BIN_LIMIT_MID) and less than or equal to the maximum-power ratio. Each medium-power channel is assigned a two-bit bin number equal to 2 (lines 30 through 31). A low-power channel has a power ratio that is greater than a predetermined minimum-power ratio (HSSCCH_BIN_LIMIT_MIN) and less than or equal to the middle-power ratio. Each low-power channel is assigned a two-bit bin number equal to 1 (lines 32 through 33). A very low-power channel has a power ratio less than or equal to the minimum-power ratio and is assigned a two-bit bin number equal to 0 (line 34).

After each channel k has been assigned a bin number, pseudocode 2900 sorts the channels from highest power to lowest power by arranging the two-bit bin numbers from largest to smallest, resulting in an eight-bit binary number (line 37 of FIG. 29(b)). This eight-bit binary number is then recalculated into a four-digit decimal number which corresponds to a three-bit look-up table index number (DeltaLUTindex=0, . . . , 7) (lines 41 through 51). As an example, a transmission that has three low-power channels and one very low-power channel produces a decimal number of 1110, which corresponds to index number 3 of the look-up table (line 46). As another example, a transmission that has one high-power channel, two medium-power channels, and a low-power channel would yield a decimal number of 3221, which corresponds to look-up table index number 7 (line 51). Note that, in this example and in certain other instances, the last two or three decimal places might not be relevant in determining the look-up table index number.

Once an index number is determined, the step size may be chosen from the look-up table. The step sizes contained in the table may be predefined by the hardware designer and may vary between applications. The selected step size is then transmitted to coefficient updater 312 of FIG. 28, where it is used to perform the coefficient calculation. Furthermore, the channel enable signal and the square root of the power ratio for each channel k are transmitted to reference calculator 2836.

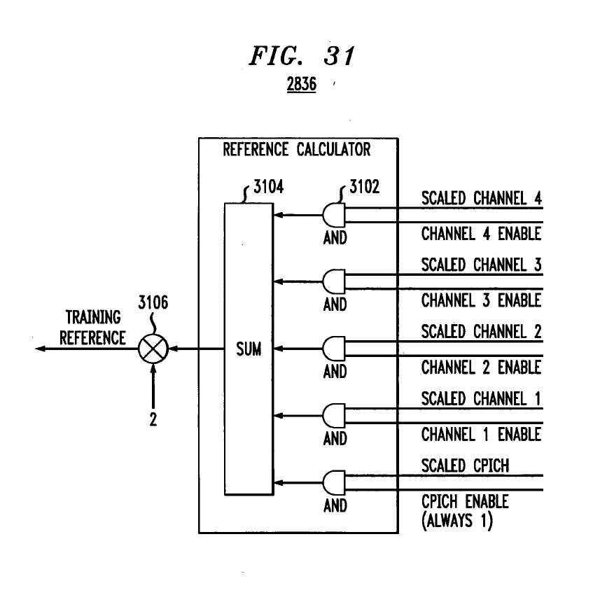

FIG. 31 shows one embodiment of reference calculator 2836 of receiver 2800 of FIG. 28. Reference calculator 2836 has “And” gates 3102 and sum block 3104. Each “And” gate 3102 receives either an HSSCCH channel from chip sequence regenerator 2826 or the CPICH channel which is known by the receiver. Additionally, each “And” gate receives a channel enable signal which corresponds to the received channel (e.g., HSSCCH_Channel_Enabled[k] of FIG. 29 for HSSCCH channel k). Note that the CPICH channel is always enabled. Before the enabled HSSCCH and CPICH channels are combined, they can be scaled as shown in Equations (13) and (14) below:

$$\begin{matrix}{ScaledChips}_{k} = \frac{\begin{matrix}{HSSCCH\_ Chips}_{k} \times \\ \sqrt{\frac{Hsscch\_Power \_Est [ k ]}{Cpich\_Power \_Estimate} \times 16}\end{matrix}}{2} & ( 13 ) \\ {ScaledChips}_{Cpich} = \frac{CPICH\_Chips}{2} & ( 14 )\end{matrix}$$

The scaled HSSCCH and CPICH chips are normalized as shown above by dividing the scaled chips by a factor of 2. The factor of 2 is derived by multiplying the square root of the scrambling code power by the square root of the spreading code power (i.e., sqrt(2)×sqrt(2)). Note that in implementations that use other spreading codes and scrambling codes, the scaled factor may be a number other than 2. Each “And” gate that receives an enabled channel then transmits the corresponding scaled chips to sum block 3104.

Sum block 3104 adds the scaled enabled channels together to form one combined reference signal. The combined reference signal is transmitted to multiplier 3106 where the reference signal is multiplied by a factor of 2. Then multiplier 3106 transmits the combined reference signal to error calculator 314 of FIG. 28.

Various embodiments of the present invention may be envisioned in which channels other than those described above are used to generate additional reference signals. Such channels may be other channels used in a 3GPP transmission or channels used in applications other than 3GPP.

Furthermore, channels other than those described above may be used as additional references without being processed by reference generator 2718. Such channels include those channels which have a bit pattern known a priori by the receiver and which are used for a purpose other than as a pilot channel. For example, in 3GPP receivers, the synchronization (SCH) channel, which is transmitted during the first 10 percent of each slot, has a bit pattern known by the receiver. This channel may be used in addition to the pilot channel so that the known reference x(i) in Equation (4) comprises pilot z(i) and the known value of the SCH channel. These additional reference channels may be used independent of the presence and use of a reference generator such as reference generator 2718.

Alternative embodiments of the present invention may be envisioned in which equalizers other than chip-rate NLMS equalizers are used in place of the main equalizer, the auxiliary equalizer, or both the main and the auxiliary equalizers. Such other equalizers include but are not limited to LMS equalizers and recursive least-squares equalizers.

Further embodiments of the present invention may be implemented in apparatuses which have two or more receivers. The two or more receivers may be adapted so that one or more receivers act as auxiliary receivers by generating additional reference signals from data signals and the other one or more receivers act as main receivers by using the additional reference signals for equalizing received signals. For example, apparatuses having a receiver that meets R99 requirements, such as a rake receiver, and an advanced receiver for receiving Release 6 or Release 7 signals could be used for this invention.

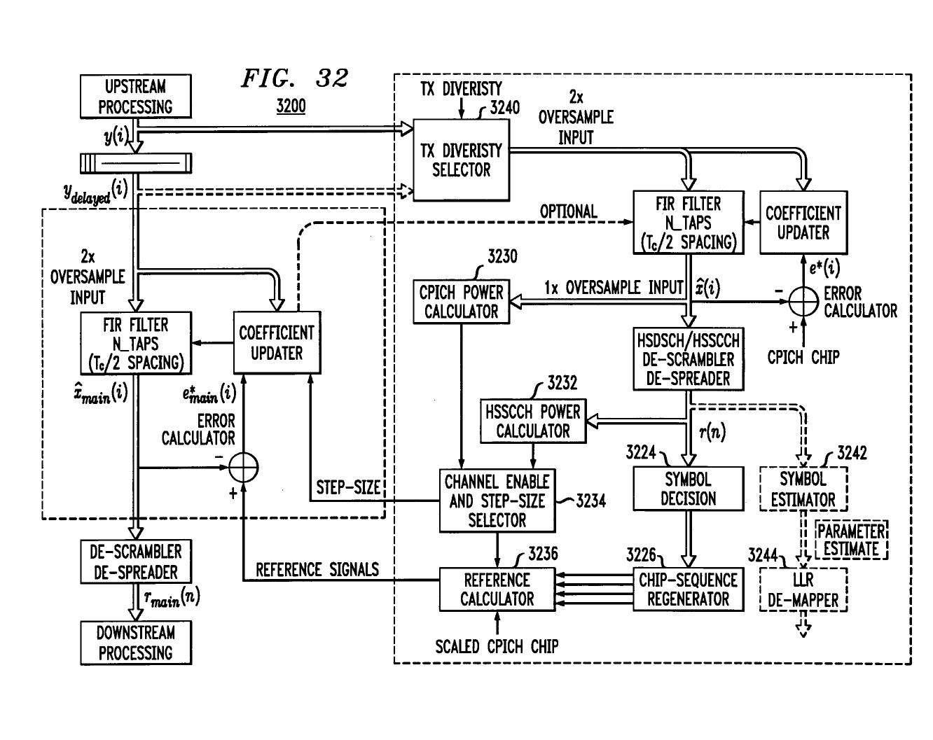

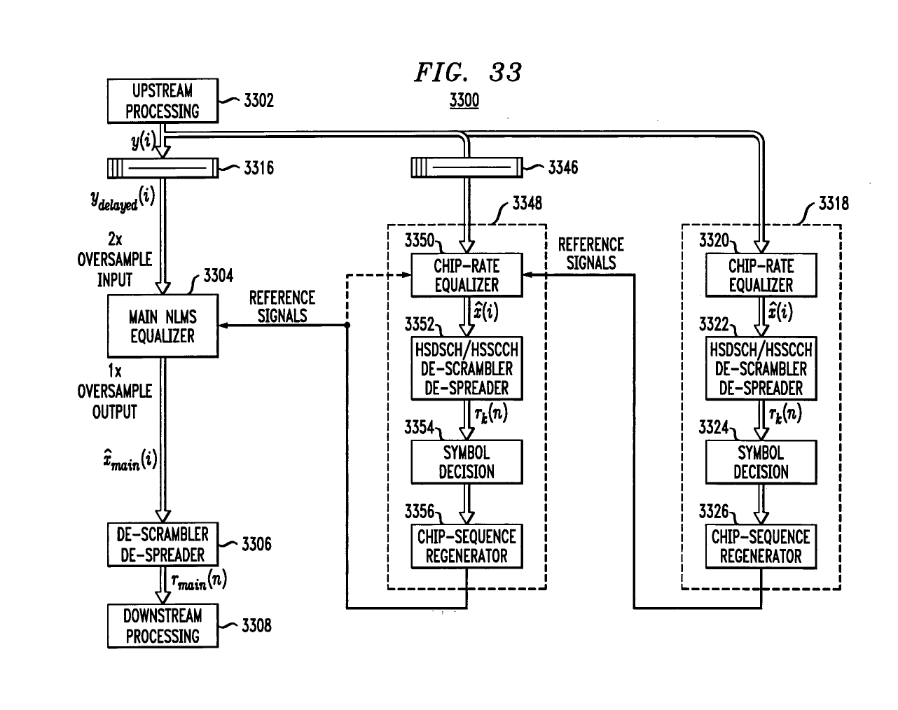

FIG. 32 shows a simplified block diagram of an apparatus 3200 according to one embodiment of the present invention that has two receivers which can be used to receive transmit-diverse signals or to generate additional reference signals. Apparatus 3200 has a diversity selector 3240 which switches the apparatus between a diversity reception mode and a reference signal generating mode. During reference signal generating mode, the diversity selector disables the downstream processing of the auxiliary receiver (i.e., symbol estimator 3242 and LLR de-mapper 3244), and apparatus 3200 performs functions analogous to those of receiver 2800 (i.e., generating reference signals and step sizes, and using the reference signals and step sizes to equalize the received signal). During diversity mode, the diversity selector disables CPICH power calculator 3230, HSSCCH power calculator 3232, channel enable and step-size selector 3234, reference calculator 3236, symbol decision block 3224, and chip-sequence regenerator 3226. In this mode, apparatus 3200 receives two transmit-diverse signals and processes the two signals independently using the two receivers.

According to yet further embodiments of the present invention, the auxiliary equalizer could use coefficients w(i) calculated by the main coefficient updater. One such embodiment of this implementation is suggested in FIG. 28. In FIG. 28, receiver 2800 has connecting line 338 which enables auxiliary equalizer 2820 to receive coefficients wₘₐᵢₙ(i) from coefficient updater 312. This function is optional and when used, auxiliary equalizer 2820 need not utilize a separate coefficient updater to calculate its own coefficients w(i). Thus, power may be conserved by not running a coefficient updater in auxiliary equalizer 2820. According to some embodiments auxiliary equalizer 2820 might not have a coefficient updater and thus would rely solely on coefficients wₘₐᵢₙ(i) received from coefficient updater 312. According to other embodiments, auxiliary equalizer 2820 might have a coefficient updater and at times equalizer 2820 could generate its own coefficients w(i) and at other times equalizer 2820 could rely on coefficients wₘₐᵢₙ(i) received from coefficient updater 312. For example, auxiliary equalizer 2820 might generate its own coefficients w(i) to improve training operations. Then, during tracking operations, auxiliary equalizer 2820 might rely on coefficients wₘₐᵢₙ(i) from coefficient updater 312 so that power may be conserved.

FIG. 33 shows a simplified block diagram of a receiver 3300 according to one embodiment of the present invention that has more than one reference generator. Apparatus 3300 has upstream processing 3302, delay buffer 3316, main NLMS equalizer 3304, descrambler and despreader 3306, and downstream processing 3308, which perform operations analogous to those of the equivalent elements of receiver 2700 of FIG. 27. Apparatus 3300 also has reference generators 3318 and 3348, which are connected in a pipelined manner. Reference generator 3318 performs operations analogous to those of reference generator 2718 to generate a first set of one or more reference signals. Reference generator 3348 receives a delayed version of received signal y(i) from delay buffer 3346 and generates a second set of one or more reference signals using the first set of one or more reference signals and possibly one or more pilot signals. The second set of one or more reference signals may then be used by main equalizer 3304 to equalize delayed received signal y_{delayed}(i). Additional embodiments may be envisioned that utilize more than two reference generators, where, except for the first reference generator, each reference generator would be connected to a previous reference generator in a pipelined manner, such that each reference generator equalizes a delayed version of the received signal using the one or more reference signals output from the previous reference generator.

Yet further embodiments of the present invention may be envisioned that iteratively generate sets of one or more reference signals. One such embodiment is suggested in FIG. 33, where reference generator 3348 shows dashed connecting line 862, which extends from chip-sequence regenerator 3356 to equalizer 3350. After generating a set of one or more reference signals, reference generator 3348 could use the set of one or more reference signals and possibly one or more pilot channels to generate a subsequent set of one or more reference signals. This iterative process could be repeated any desired number of times before applying the final set of one or more reference signals to main NLMS equalizer 3304.

By maintaining the pilot power and generating additional sets of one or more reference signals iteratively or through the use of additional reference generators, the accuracy of the final set of one or more reference signals in approximating the originally transmitted signal may be increased. On the other hand, the pilot power can be decreased with the generation of additional sets of one or more reference signals and the accuracy of the final set of one or more reference signals may be maintained. Other implementations can achieve both reduced pilot power and increased accuracy of the final set of one or more reference signals by partially reducing the power and/or number of pilot channels.

While FIG. 33 shows an embodiment having two reference generators 3318 and 3348 where reference generator 3348 is capable of iteratively generating sets of one or more reference signals, the present invention is not so limited. Various embodiments can be envisioned which use one reference generator or multiple, pipelined reference generators, of which at least one reference generator may support iterative generation of sets of one or more reference signals. The design of such embodiments may take into account the tradeoffs of using pipelined reference generators, iterative generation, or both. In particular, iteratively generating sets of one or more reference signals requires less hardware and consumes less power than pipelined reference generators. On the other hand, the latency of pipelined reference generators may be less than that of iterative processing, since a previous reference generator may be used for processing the next set of received signals, while the subsequent reference generator is processing a particular set of received signals. Various embodiments may balance these tradeoffs by combining the two approaches.

As used in the specification, the term “pilot” refers to any signal having a bit pattern known a priori by the receiver. As such, the term “pilot” includes both traditional pilot channels that have no use other than for training as well as known channels that have other uses such as the synchronization channel (SCH) used in 3rd Generation Partnership Project (3GPP) receivers. Accordingly, reference signal z(i) in FIG. 27 may be based on channels traditionally used for receiver functions other than as pilots (e.g., SCH) in addition to or instead of one or more other pilot channels.

The present invention may be implemented as circuit-based processes, including possible implementation as a single integrated circuit (such as an ASIC or an FPGA), a multi-chip module, a single card, or a multi-card circuit pack. As would be apparent to one skilled in the art, various functions of circuit elements may also be implemented as processing blocks in a software program. Such software may be employed in, for example, a digital signal processor, micro-controller, or general-purpose computer.

The present invention can be embodied in the form of methods and apparatuses for practicing those methods. The present invention can also be embodied in the form of program code embodied in tangible media, such as magnetic recording media, optical recording media, solid state memory, floppy diskettes, 39-ROMs, hard drives, or any other machine-readable storage medium, wherein, when the program code is loaded into and executed by a machine, such as a computer, the machine becomes an apparatus for practicing the invention. The present invention can also be embodied in the form of program code, for example, whether stored in a storage medium, loaded into and/or executed by a machine, or transmitted over some transmission medium or carrier, such as over electrical wiring or cabling, through fiber optics, or via electromagnetic radiation, wherein, when the program code is loaded into and executed by a machine, such as a computer, the machine becomes an apparatus for practicing the invention. When implemented on a general-purpose processor, the program code segments combine with the processor to provide a unique device that operates analogously to specific logic circuits.

Unless explicitly stated otherwise, each numerical value and range should be interpreted as being approximate as if the word “about” or “approximately” preceded the value of the value or range.

It will be further understood that various changes in the details, materials, and arrangements of the parts which have been described and illustrated in order to explain the nature of this invention may be made by those skilled in the art without departing from the scope of the invention as expressed in the following claims.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the present invention.

Although the elements in the following method claims are recited in a particular sequence with corresponding labeling, unless the claim recitations otherwise imply a particular sequence for implementing some or all of those elements, those elements are not necessarily intended to be limited to being implemented in that particular sequence.

Also, for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

1. A method for processing received signals, the method comprising:
(a) receiving first and second signals;
(b) equalizing the first received signal using one or more pilot reference signals to provide a first equalized signal;
(c) decoding one or more data channels of the first equalized signal to recover an original data sequence for the one or more data channels; and
(d) equalizing the second received signal using, as a reference signal, the recovered original data sequence, in combination with one or more pilot reference signals; wherein:
the equalizing in steps (b) and (d) comprises:
(i) using a filter to filter the received signal based on a set of filter tap coefficients adaptively generated by calculating an error signal, and
(ii) updating the filter tap coefficients based on the error signal;
the filter has a sampling window defining a time span during which signal samples are gathered; and
the sampling window is adaptable, based on a changing position of one or more rays, each ray being a version of one of the first and second signals that travels along a given path.

2. The invention of claim 1, wherein the second received signal is a time-delayed version of the first received signal.

3. The invention of claim 2, wherein steps (b) and (d) are performed concurrently by combining the first and second received signals during a single equalizing operation using shared hardware to provide a single equalized signal.

4. The invention of claim 2, wherein:
step (b) is performed to generate a set of auxiliary filter tap coefficients; and
step (d) is performed to generate, based on the second received signal and the set of auxiliary filter tap coefficients, a set of main filter tap coefficients.

5. The invention of claim 1, wherein the step of updating the filter tap coefficients based on the error signal comprises:
calculating an average of one or more sets of filter tap coefficients to generate one or more sets of averaged filter tap coefficients; and
updating the filter tap coefficients using the one or more sets of averaged filter coefficients.

6. The invention of claim 1, wherein the equalizing in steps (b) and (d) is performed by shared hardware adapted to be selectively coupled and decoupled to receive selectively signals originating at one or more antennas.

7. The invention of claim 1, further comprising:
generating a data block based on one or more of the first and second equalized signals;
storing the data block in compressed form;
receiving an automatic repeat request (ARQ) for retransmission of the generated data block;
retrieving the stored compressed data block; and
combining the stored compressed data block with a retransmitted version of the generated data block.

8. The invention of claim 1, further comprising:
generating data-channel blocks and control-channel blocks based on one or more of the first and second equalized signals;
monitoring one or more of the control-channel blocks to determine whether data in the form of a corresponding data-channel block is to be received; and
if the monitoring of the one or more control-channel blocks determines that no data-channel block is to be received, then reducing power to one or more circuits adapted to process the data-channel block.

9. The invention of claim 1, further comprising:
generating a data block based on one or more of the first and second equalized signals; and
using a buffer-based method to generate a spreading-code sequence; and
despreading the data block using the generated spreading-code sequence.

10. The invention of claim 1, wherein:
steps (b) and (d) are performed by a first processing block;
additional processing of the received signals is performed by other processing blocks; and
the other processing blocks comprise:
a second processing block adapted to receive an input signal and generate from the input signal one or more processing parameters;
a delay block adapted to generate a delayed signal; and
a third processing block adapted to apply the one or more processing parameters to the delayed signal to generate an output signal, wherein the delay block compensates for one or more processing delays associated with the generation of the one or more processing parameters by the second processing block.

11. The invention of claim 1, further comprising:
generating a data block based on one or more of the first and second equalized signals;
generating interleaver addresses for turbo decoding by:
performing a training mode in which an address generator is controlled to output required addresses for coding a related block size;
storing any invalid addresses output from the address generator during the training mode into a pruning avoidance buffer; and
generating a sequence of contiguous valid coding addresses for the related block size from an address computation module; wherein a stream of valid, contiguous coding address are generated for all specified code block sizes; and
performing turbo decoding of the data block based on the generated interleaver addresses.

12. The invention of claim 1, further comprising:
generating a data block based on one or more of the first and second equalized signals;
performing turbo decoding of the data block, wherein the turbo decoding comprises a method for manipulating extrinsic values in a turbo decoder having non-normalizing branch metric value (gamma) calculation logic and interleaving memory, comprising the steps of:
applying a normalization factor to newly calculated extrinsic values before they are written to interleaving memory; and
applying an inverse of the normalization factor to previously calculated extrinsic values after they are read from interleaving memory; wherein the branch metric value calculation logic does not normalize calculated branch metric values.

13. The invention of claim 1, further comprising:
generating a data block based on one or more of the first and second equalized signals;
computing a metric to determine selection of a scrambled data channel before receipt of the entire data lock by:
decoding an initial portion of the data block received in one of a plurality of data channels;
re-encoding the initial portion of the block of data;
computing a value related to a number of mismatched data symbols, based on a comparison of the re-encoded portion of data and the corresponding received data block; and
selecting a best one of the plurality of data channels, based on accumulation of the computed value being beyond a given threshold value.

14. The invention of claim 1, further comprising:
generating a data block based on one or more of the first and second equalized signals;
generating one or more despread values corresponding to application of one or more despreading codes to a sequence of spread values by:
(a) storing a pair of spread values in one or more data buffers; and
(b) generating and storing one or more pairs of sum and difference values in the one or more data buffers, wherein each pair of sum and difference values is generated by:
(1) reading a pair of values from the one or more data buffers;
(2) generating a sum of the pair of values; and
(3) generating a difference of the pair of values.

15. The invention of claim 1, wherein one or more of the first and second equalized signals comprises a pilot signal; and further comprising:
estimating the Doppler frequency of the input signal comprising the pilot signal by:
(1) accumulating a plurality of samples from the input signal over a specified time duration to derive a channel tap estimate;
(2) obtaining a sequence of channel tap estimates by repeating step (1) until a specified number of channel tap estimates have been accumulated;
(3) performing a Fourier transform of the sequence of channel tap estimates to obtain a complex sequence of values;
(4) finding an index value for which a power spectral distribution function of the complex sequence of values exceeds a specified threshold; and
(5) obtaining an estimate of the Doppler frequency by dividing the index value found in step (4) by the product of the specified number of channel tap estimates and the specified time duration.

16. Apparatus for processing received signals, the apparatus adapted to:
(a) receive first and second signals;
(b) equalize the first received signal using one or more pilot reference signals to provide a first equalized signal;
(c) decode one or more data channels of the first equalized signal to recover an original data sequence for the one or more data channels; and
(d) equalize the second received signal using, as a reference signal, the recovered original data sequence, in combination with one or more pilot reference signals; wherein:
the equalizing in steps (b) and (d) comprises:
(i) using a filter to filter the received signal based on a set of filter tap coefficients adaptively generated by calculating an error signal, and
(ii) updating the filter tap coefficients based on the error signal;
the filter has a sampling window defining a time span during which signal samples are gathered; and
the sampling window is adaptable, based on a changing position of one or more rays, each ray being a version of one of the first and second signals that travels along a given path.
